(19) United States
(12) Patent Application Publication
(10) Pub. No.: US 2026/0256000 A1
(43) Pub. Date: Aug. 27, 2026

(54) INTERPOSER, SEMICONDUCTOR PACKAGE INCLUDING INTERPOSER, AND TESTING METHOD FOR INTERPOSER

(71) Applicant: SAMSUNG ELECTRONICS CO., LTD., Suwon-si (KR)

(72) Inventors: Seungwon BAEK, Suwon-si (KR); Minkyu KIM, Suwon-si (KR); Joongsun KIM, Suwon-si (KR); Pyunghwa HAN, Suwon-si (KR); Kyuil HWANG, Suwon-si (KR)

(73) Assignee: SAMSUNG ELECTRONICS CO., LTD., Suwon-si (KR)

(21) Appl. No.: 19/404,270

(22) Filed: Dec. 1, 2025

(30) Foreign Application Priority Data
Feb. 25, 2025 (KR) 10-2025-0024514

(51) Int. Cl. H10W 70/65; G01R 31/28; H10W 70/60; H10W 70/685; H10W 90/00

(52) U.S. Cl. CPC H10W 70/65; G01R 31/2896; H10W 70/611; H10W 70/685; H10W 90/00

(57) ABSTRACT

Provided are an interposer capable of early testing for defects without using an intermediate medium, a semiconductor package including the interposer, and a testing method for the interposer. The interposer includes a body layer, a wiring layer disposed on the body layer, a through post penetrating through the body layer, an interposer pad disposed on the wiring layer, and a test pad disposed on a connection area of the wiring layer and connected to a part of the interposer pad.

### CROSS-REFERENCE TO RELATED APPLICATION

This application is based on and claims priority under 35 U.S.C. §119 to Korean Patent Application No. 10-2025-0024514, filed on Feb. 25, 2025, in the Korean Intellectual Property Office, the disclosure of which is incorporated by reference herein in its entirety.

### BACKGROUND

The inventive concept relates to a semiconductor package, and more particularly, to an interposer including a test pad, and a semiconductor package including the interposer.

With the rapid development of the electronics industry and the demands of users, electronic devices are becoming smaller and lighter. As electronic devices become smaller and lighter, semiconductor packages used therein are also becoming smaller and lighter. In addition, the semiconductor packages are also required to have high reliability along with high performance and large capacity. To achieve smaller and lightweight semiconductor packages with high performance, large capacity, and high reliability, research and development are continuously being conducted on semiconductor chips including through-silicon via (TSV) structures, and semiconductor packages with a structure where these semiconductor chips are stacked. In addition, in such semiconductor packages, an interposer that connects the semiconductor devices arranged thereon to each other or to a package substrate is mounted on the package substrate and used as an intermediate substrate.

### SUMMARY

The inventive concept provides an interposer capable of early testing for defects without using an intermediate medium, a semiconductor package including the interposer, and a testing method for the interposer.

In addition, the inventive concept is not limited to the above. The other inventive concepts may be clearly understood by those skilled in the art.

According to an aspect of the inventive concept, there is provided an interposer including a body layer, a wiring layer disposed on the body layer, a through post penetrating through the body layer, an interposer pad disposed on the wiring layer, and a test pad disposed on a connection area of the wiring layer and connected to a portion of the interposer pad.

According to another aspect of the inventive concept, there is provided a semiconductor package including a package substrate, an interposer on the package substrate, at least one first semiconductor device arranged in a central portion on an upper surface of the interposer in a first direction, and second semiconductor devices disposed on the upper surface of the interposer on both sides of the at least one first semiconductor device in the first direction, in which the interposer includes a body layer, a wiring layer disposed on the body layer, a through post penetrating through the body layer, an interposer pad disposed on the wiring layer, and a test pad disposed on a connection area of the wiring layer and connected to a portion of the interposer pad.

According to another aspect of the inventive concept, there is provided a semiconductor package including a package substrate, an interposer on the package substrate, at least one logic device arranged in a central portion of an upper surface of the interposer in a first direction, and a high bandwidth memory (HBM) package disposed on the upper surface of the interposer on both sides of the at least one logic device in the first direction, in which the interposer includes a body layer, a wiring layer disposed on the body layer, a Si-bridge arranged in the body layer and the wiring layer, a through post penetrating through the body layer, an interposer pad disposed on the wiring layer and the Si-bridge, and a test pad disposed on the Si-bridge and connected to a portion of the interposer pad.

According to another aspect of the inventive concept, there is provided a testing method for an interposer performing an interim test on a state of wires in a connection area through a test pad, in which the interposer includes a body layer, a wiring layer disposed on the body layer, a through post penetrating through the body layer, an interposer pad disposed on the wiring layer, and a test pad disposed on the connection area of the wiring layer and connected to a part of the interposer pad.

According to an embodiment, the interposer includes an Si-bridge arranged in the wiring layer and the body layer, in which the Si-bridge constitutes the connection area, the test pad is arranged on the Si-bridge, and a test on a state of wires of the Si-bridge may be performed through the test pad.

According to an embodiment, when a first semiconductor device is arranged at a central portion of the upper surface of the interposer in a first direction and second semiconductor devices are arranged on both sides of the first semiconductor device in the first direction, the Si-bridge includes a first Si-bridge overlapping a portion of each of the first semiconductor device and the second semiconductor device on one side of the first semiconductor device in the first direction, and a second Si-bridge overlapping a portion of each of the first semiconductor device and the second semiconductor device on the other side of the first semiconductor device in the first direction, in which, before the first semiconductor device and the second semiconductor device are mounted on the interposer, the state of the wires of each of the first Si-bridge and the second Si-bridge may be tested.

According to an embodiment, the test pad include a first test pad on the first Si-bridge and a second test pad on the second Si-bridge, and after testing the state of wires of the first Si-bridge through the first test pad, the state of wires of the second Si-bridge may be tested through the second test pad.

According to an embodiment, the first test pad and the second test pad are arranged in a symmetrical structure, and after testing using the first test pad, the interposer or test device may be rotated 180° in a test using the second test pad.

According to an embodiment, when multiple second semiconductor devices are arranged on each side of the first semiconductor device, multiple first Si-bridges and multiple second Si-bridges are arranged corresponding to the second semiconductor devices, and the state of the wires of each of the multiple second Si-bridges may be tested after testing the state of the wires of each of the multiple of first Si-bridges.

According to an embodiment, the multiple first Si-bridges may be implemented in one semiconductor chip and the multiple second Si-bridges are implemented in one semiconductor chip, or each of the multiple first Si-bridges may be implemented as a semiconductor chip and each of the multiple second Si-bridges may be implemented as a semiconductor chip.

According to an embodiment, the first Si-bridge and the second Si-bridge each include a plurality of net lines, the first test pad is connected to first net lines, which are some of the net lines, and the second test pad is connected to second net lines, which are some of the net lines, and the first net lines and the second net lines may be selected from among the net lines based on the length of the net line, the number of interposer pads connected to the net lines, or other set criteria.

According to an embodiment, when a first semiconductor device and a second semiconductor device are arranged adjacent to each other on the upper surface of the interposer, the first semiconductor device and the second semiconductor device are connected to the interposer pad on the connection area, the pitch of the test pad is greater than the pitch of the interposer pad, and the state of the wires in the connection area may be tested without the intermediate medium.

According to an embodiment, when a first semiconductor device and a second semiconductor device are arranged adjacent to each other on the upper surface of the interposer, the first semiconductor device and the second semiconductor device are connected to the interposer pad on the connection area, and before the first semiconductor device and the second semiconductor device are mounted on the interposer, the state of the wires in the connection area may be tested.

### BRIEF DESCRIPTION OF THE DRAWINGS

Embodiments will be more clearly understood from the following detailed description taken in conjunction with the accompanying drawings in which:

FIGS. 1A, 1B, and 1C are respectively a plan view, a cross-sectional view, and an enlarged view of an interposer, according to an embodiment;

FIGS. 2A and 2B are conceptual views illustrating a wire structure of a silicon (Si)-bridge in the interposer of FIG. 1A;

FIGS. 3A and 3B are conceptual views illustrating a connection structure between a test pad and an interposer pad of the Si-bridge within the interposer in FIG. 1A;

FIGS. 4A and 4B are conceptual views showing the arrangement locations of the test pad and the interposer pad of the Si-bridge in the interposer of FIG. 1A;

FIGS. 5A and 5B are conceptual views showing the chip structure of the Si-bridge in the interposer of FIG. 1A;

FIGS. 6A and 6B are respectively a cross-sectional view and an enlarged view of an interposer according to an embodiment;

FIGS. 7, 8, 9, and 10 are plan views and a cross-sectional view of the interposer according to embodiments;

FIGS. 11A and 11B are respectively a perspective view and a cross-sectional view of a semiconductor package including the interposer, according to an embodiment;

FIG. 12 is a perspective view of the semiconductor package including the interposer, according to an embodiment;

FIGS. 13A and 13B are conceptual diagrams showing differences between a testing method for the interposer of a comparative example and a testing method for the interposer of an embodiment; and

FIGS. 14A, 14B, 14C, and 14D are conceptual diagrams schematically illustrating the testing method for the interposer, according to an embodiment.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted.

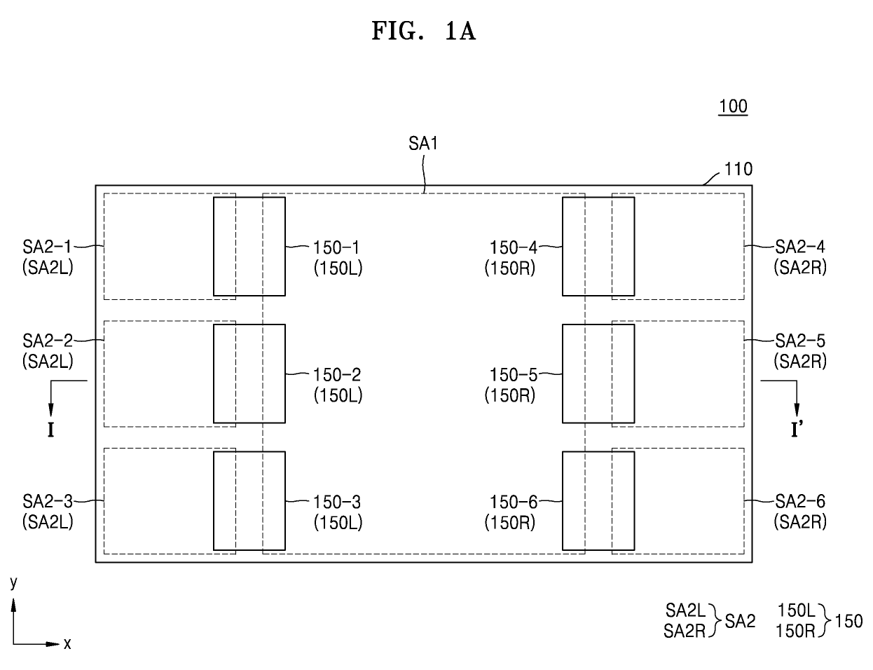

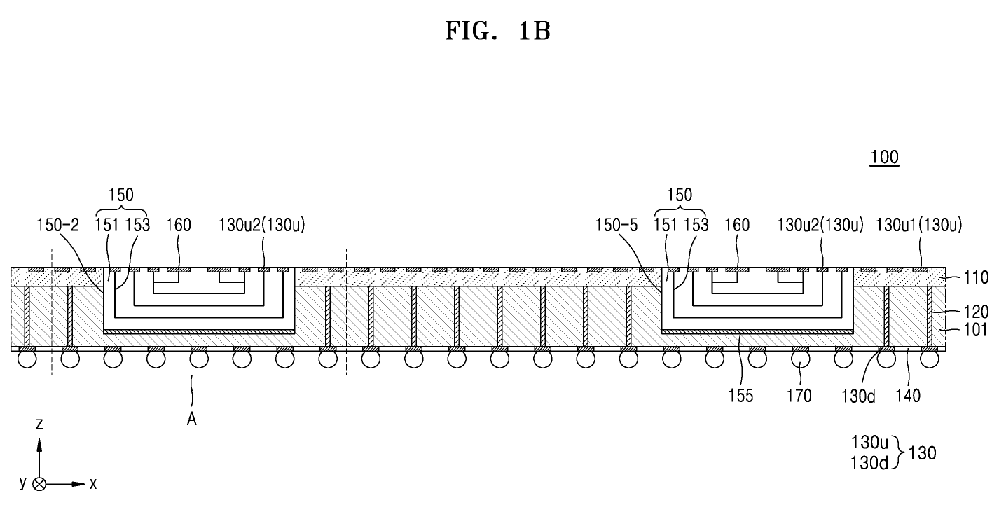

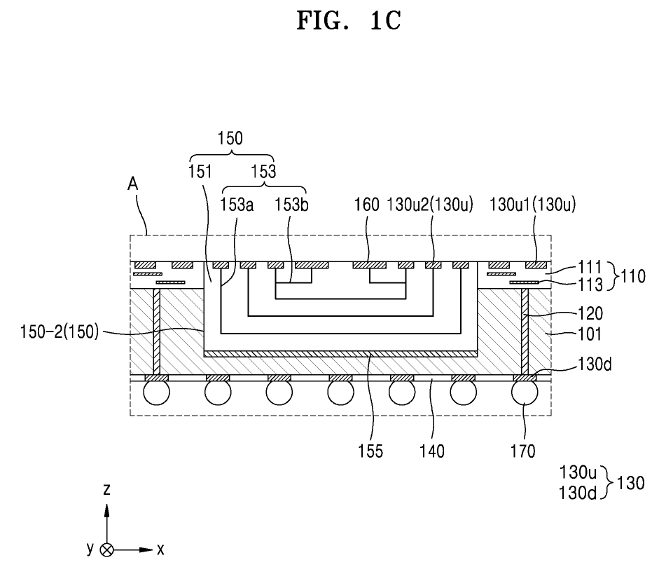

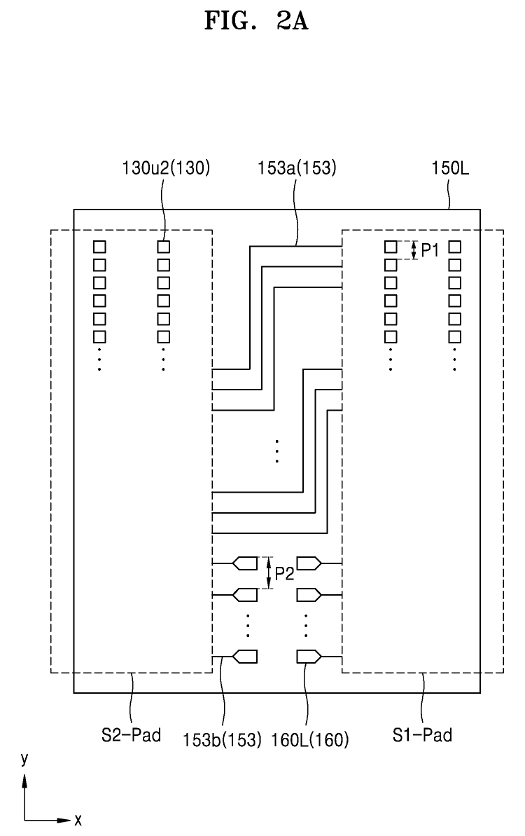

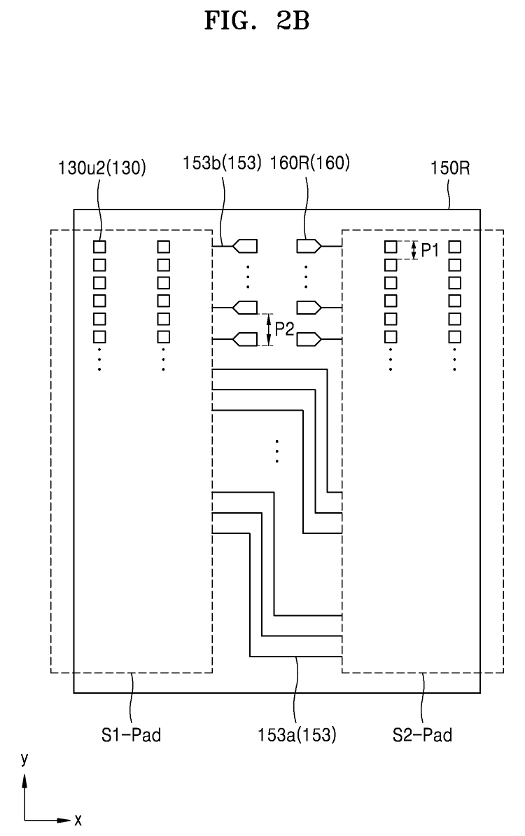

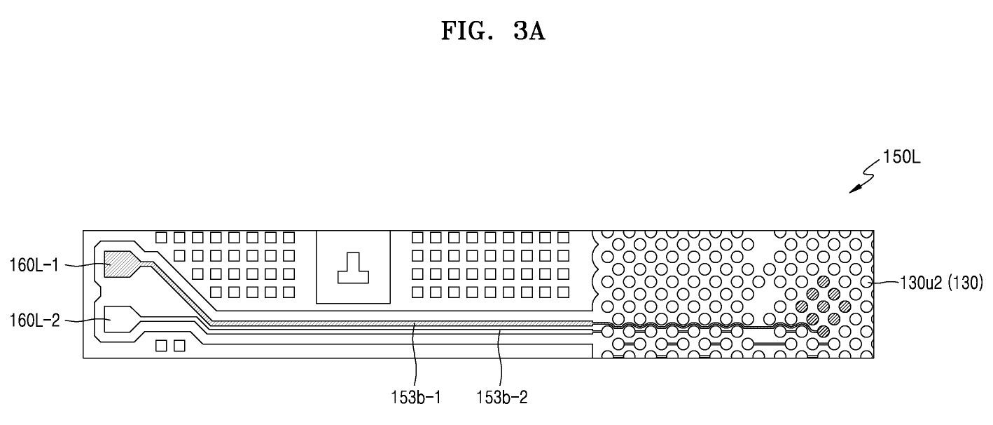

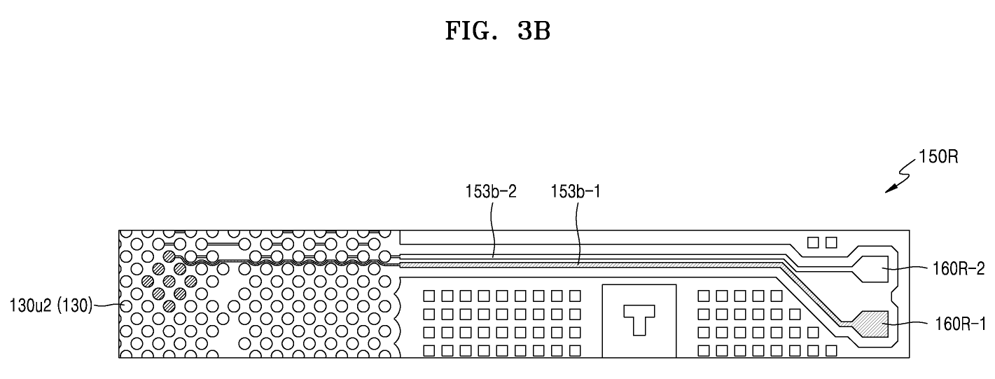

FIGS. 1A to 1C are respectively a plan view, a cross-sectional view, and an enlarged view of an interposer, according to an embodiment, where FIG. 1B is a cross-sectional view taken along line I-I′ in FIG. 1A, and FIG. 1C is an enlarged view of portion A in FIG. 1B. FIGS. 2A and 2B are conceptual views illustrating a wire structure of a silicon (Si)-bridge in the interposer of FIG. 1A, and FIGS. 3A and 3B are conceptual views illustrating a connection structure between a test pad and an interposer pad of the Si-bridge within the interposer in FIG. 1A.

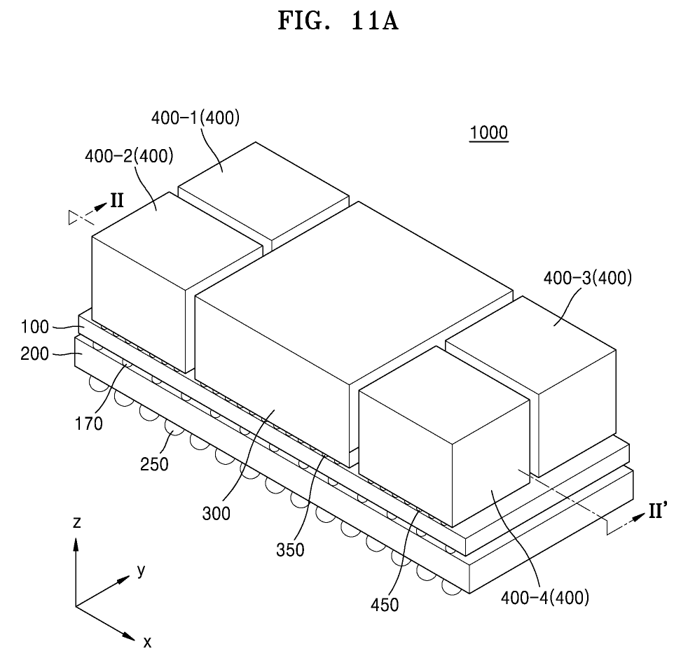

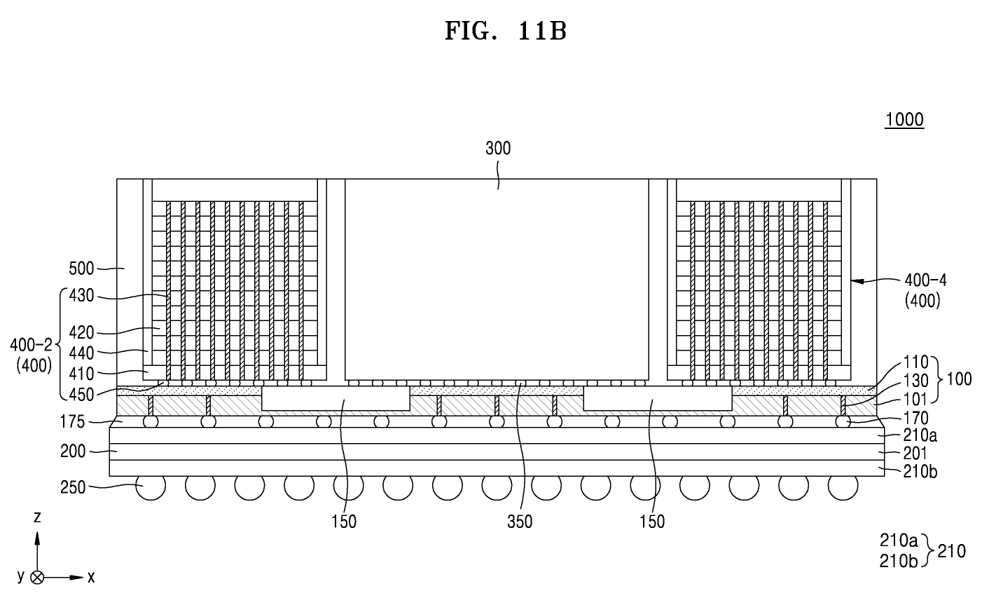

Referring to FIGS. 1A to 3B, an interposer 100 of an embodiment may mediate signal transmission between semiconductor devices mounted on an upper surface of the interposer 100. For example, a first semiconductor device (300 in FIG. 11A) and a second semiconductor device (400 in FIG. 11A) may be mounted on the upper surface of the interposer 100, and the interposer 100 may mediate signal transmission between the first semiconductor device 300 and the second semiconductor device 400. In addition, the interposer 100 may be mounted on a package substrate (200 in FIG. 11A) and may mediate transmission of signals, power, or the like between semiconductor devices and a package substrate 200. The interposer 100 of an embodiment may include a 2.3D package interposer. In some embodiments, the interposer 100 may be referred to as a panel level package (PLP) interposer or a redistribution layer (RDL) interposer.

For reference, an interposer may largely include a 2.5D package interposer and a 2.3D package interposer. The 2.5D package interposer usually refers to a Si-interposer and may include a through silicon via (TSV) therein. The 2.3D package interposer may refer to an organic or inorganic interposer. In the case of the organic interposer, polyimide (PI), benzocyclobutene (BCB), and polybenzoxazole (PBO) may be used as a body layer. In the case of the inorganic interposer, ceramic or glass may be used as a body layer. When the 2.3D package interposer includes a through electrode, the through electrode may be referred to as a through dielectric via (TDV), or a through glass via (TGV), depending on the material of the body layer. In some embodiments, on the other hand, the interposer may be further subdivided, including the Si-bridge. Accordingly, a structure excluding the 2.5D package interposer is also referred to as a 2.xD package interposer.

The interposer 100 of an embodiment may include a body layer 101, a wiring layer 110, through posts 120, interposer pads 130, a protective layer 140, a Si-bridge 150, test pads 160, and first connection terminals 170. The body layer 101 may include the organic or inorganic material, as described above.

The wiring layer 110 may be disposed on an upper surface of the body layer 101. The wiring layer 110 may be connected to semiconductor devices disposed on the upper surface of the interposer 100. In some embodiments, the wiring layer 110 may be referred to as an RDL, a front-side wiring layer, or a front-side RDL. The front side may refer to that the wiring layer 110 is directed to a front side that is an active surface of the semiconductor devices.

The wiring layer 110 may include an interlayer insulating layer 111 and wiring lines 113. The interlayer insulating layer 111 may include an insulating material, for example, a photo imageable dielectric (PID) or a photo imageable polyimide (PIP) resin and may further include an inorganic filler. However, the material of the interlayer insulating layer 111 is not limited to the above. For example, the interlayer insulating layer 111 may include a polymide isoindro quirazorindione (PIQ), a PI, a PBO, or the like.

The interlayer insulating layer 111 may have a multilayer structure, according to the multilayer structure of the wiring lines 113. However, in FIGS. 1B and 1C, for convenience, the interlayer insulating layer 111 is shown as a single layer structure. On the other hand, when the interlayer insulating layer 111 has a multilayer structure, all layers of the interlayer insulating layer 111 may include the same material or at least one layer may include a different material.

The wiring lines 113 may be arranged as multiple layers in the interlayer insulating layer 111. The wiring lines 113 arranged in different layers may be connected to each other by vertical vias (which may be not shown in the drawings). The wiring lines 113 and the vertical vias may include, for example, copper (Cu). However, the material of the wiring lines 113 and the vertical vias is not limited to Cu. In some embodiments, the wiring lines 113 may be referred to as redistribution lines.

The through posts 120 may extend through the body layer 101. The top of the through post 120 may be connected to the wiring lines 113 of the wiring layer 110. In addition, the bottom of the through post 120 may be connected to the interposer pad 130, e.g., a lower interposer pad 130d.

The through post 120 may include, for example, Cu. Accordingly, the through post 120 may be referred to as a Cu post. However, the material of the through post 120 is not limited to Cu. The through post 120 may be formed through electroplating using a seed metal. The seed metal may include various metal materials, such as Cu, titanium (Ti), tantalum (Ta), titanium nitride (TiN), and tantalum nitride (TaN). In the interposer 100 of an embodiment, the seed metal may be included as part of the through post 120. In some embodiments, the through post 120 may be referred to as a through electrode.

The interposer pad 130 may include an upper interposer pad 130u and a lower interposer pad 130d. The upper interposer pad 130u may be disposed on an upper surface of the wiring layer 110. In addition, the upper interposer pad 130u may also be disposed on an upper surface of the Si-bridge 150. For example, the upper interposer pad 130u may include a first upper interposer pad 130u1 on the upper surface of the wiring layer 110 and a second upper interposer pad 130u2 on the Si-bridge 150. In addition, the first upper interposer pad 130u1 may be connected to the wiring lines 113 of the wiring layer 110, and the second upper interposer pad 130u2 may be connected to wires 153 of the Si-bridge 150. On the other hand, connection terminals of the semiconductor devices subsequently mounted on the interposer 100 may be disposed on the upper interposer pads 130u.

The lower interposer pad 130d may be disposed on a lower surface of the body layer 101. The lower interposer pad 130d may be connected to the through post 120. However, as shown in FIG. 1B, a portion of the lower interposer pad 130d may not be connected to the through post 120. The lower interposer pad 130d, which is not connected to the through post 120, may include a dummy pad.

The protective layer 140 may be disposed on a lower surface of the interposer 100, for example, the lower surface of the body layer 101. Although not shown, the protective layer 140 may also be disposed on the upper surface of the interposer 100, for example, the upper surface of the wiring layer 110. The lower interposer pad 130d may penetrate through the protective layer 140. For example, the lower interposer pad 130d may be connected to the through post 120 through the protective layer 140. The protective layer 140 may include, for example, an oxide film, a nitride film, a carbide film, a polymer, or a combination thereof. However, the material of the protective layer 140 is not limited thereto. The protective layer 140 may have a single-layer or multi-layer structure.

The Si-bridge 150 may be arranged within the interposer 100. For example, the Si-bridge 150 may be arranged in the body layer 101 and the wiring layer 110 of the interposer 100. In some embodiments, the Si-bridge 150 may be referred to as a Si-bridge interposer. The Si-bridge 150 may connect the first semiconductor device (300 in FIG. 11A) to the second semiconductor device (400 in FIG. 11B) mounted on the interposer 100. Accordingly, the Si-bridge 150 may be arranged inside the interposer 100 at a corresponding position between the first semiconductor device 300 and the second semiconductor device 400. In addition, the Si-bridge 150 may overlap a portion of the first semiconductor device 300 and a portion of the second semiconductor device 400 together.

Specifically, in the interposer 100 of an embodiment, the first semiconductor device 300 may be mounted on a first semiconductor area SA1 in the central portion of the upper surface of the interposer 100 in an X direction. The second semiconductor device 400 may be mounted on a second semiconductor area SA2 in the outer portion of the upper surface of the interposer 100 on both sides of the first semiconductor area SA1 in the X direction. The second semiconductor area SA2 may include a left second semiconductor area SA2L disposed on the left side of the first semiconductor area SA1 in the X direction and a right second semiconductor area SA2R disposed on the right side of the first semiconductor area SA1.

Three second semiconductor devices 400 may be mounted on each of both sides of the first semiconductor device 300. Accordingly, as shown in FIG. 1A, the left second semiconductor area SA2L may include a first mounting area SA2-1, a second mounting area SA2-2, and a third mounting area SA2-3 disposed on the left side of the first semiconductor area SA1 in the X direction. In addition, the right second semiconductor area SA2R may include a fourth mounting area SA2-4, a fifth mounting area SA2-5, and a sixth mounting area SA2-6 disposed on the right side of the first semiconductor area SA1 in the X direction.

On the other hand, the Si-bridge 150 may include a left Si-bridge 150L disposed on the left side of the first semiconductor area SA1 in the X direction and a right Si-bridge 150R disposed on the right side of the first semiconductor area SA1. The left Si-bridge 150L may be arranged to overlap a portion of the left second semiconductor area SA2L on the left side and a portion of the first semiconductor area SA1 on the left side in the X direction together. In addition, the right Si-bridge 150R may be arranged to overlap a portion of the right second semiconductor area SA2R on the right side and a portion of the first semiconductor area SA1 on the right side in the X direction together. On the other hand, since the left second semiconductor area SA2L includes three mounting areas, the left Si-bridge 150L may include a first Si-bridge 150-1, a second Si-bridge 150-2, and a third Si-bridge 150-3 on the left side of the first semiconductor area SA1. In addition, since the right second semiconductor area SA2R includes three mounting areas, the right Si-bridge 150R may include a fourth Si-bridge 150-4, a fifth Si-bridge 150-5, and a sixth Si-bridge 150-6 on the right side of the first semiconductor area SA1.

The left Si-bridge 150L and the right Si-bridge 150R may have a symmetrical structure. For example, the test pads 160 of the left Si-bridge 150L and the right Si-bridge 150R may be arranged to be symmetrical to each other. In addition, the wire connection structure of the left Si-bridge 150L connecting the first semiconductor device 300 to the second semiconductor device 400 on the left side may be symmetrical to the wire connection structure of the right Si-bridge 150R connecting the first semiconductor device 300 to the second semiconductor device 400 on the right side. Here, being symmetric may refer to a point symmetry. Accordingly, when the right Si-bridge 150R is rotated by 180°, the test pad and the wire connection structure of the right Si-Bridge 150R may match the test pad and the wire connection structure of the left Si-bridge 150L. The symmetrical structure of the left Si-bridge 150L and the right Si-bridge 150R is described in detail below with reference to FIGS. 2A to 3B.

Hereinafter, the second Si-bridge 150-2 of the left Si-bridge of 150L is described for convenience.

The second Si-bridge 150-2 may be arranged inside the body layer 101 and the wiring layer 110. Specifically, the second Si-bridge 150-2 may be arranged in a trench formed in the body layer 101 and the wiring layer 110 and may be bonded and fixed to the body layer 101 on the bottom of the trench through an adhesive layer 155. In some embodiments, the adhesive layer 155 may be omitted. The body layer 101 may be kept thin at the bottom of the second Si-bridge 150-2.

The second Si-bridge 150-2 may include a bridge body 151 and a wire 153. The bridge body 151 may include, for example, Si. The wire 153 may be arranged within the bridge body 151. The wire 153 may include a bridge wire 153a and a test wire 153b. The bridge wire 153a may be connected to a second interposer pad 130u2. A signal may be transmitted between the first semiconductor device 300 and the second semiconductor device 400 through the second interposer pad 130u2 and the bridge wire 153a. The test wire 153b may be connected to the test pad 160. In addition, the test wire 153b may also be connected to the second interposer pad 130u2. The state of the bridge wire 153a may be tested through the test pad 160 and the test wire 153b.

The test pad 160 may be disposed on an upper surface of the second Si-bridge 150-2. Specifically, the test pad 160 may be disposed on an upper surface of the bridge body 151. On the other hand, the second interposer pad 130u2 may also be disposed on the upper surface of the bridge body 151. As shown in FIG. 1C, the size and the pitch of the test pad 160 may be greater than the size and the pitch of the second interposer pad 130u2. For example, as shown in FIG. 2A, in a Y direction, the second interposer pad 130u2 may have a first pitch P1, and the test pad 160 may have a second pitch P2. The second pitch P2 may be greater than the first pitch P1.

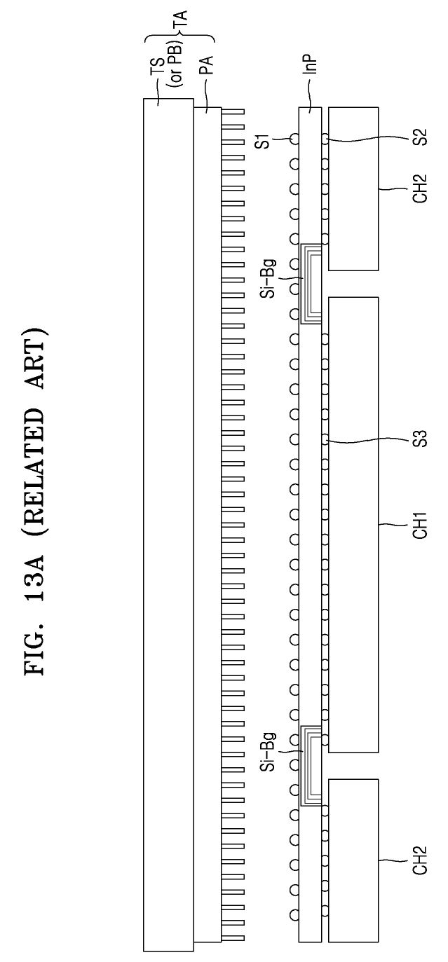

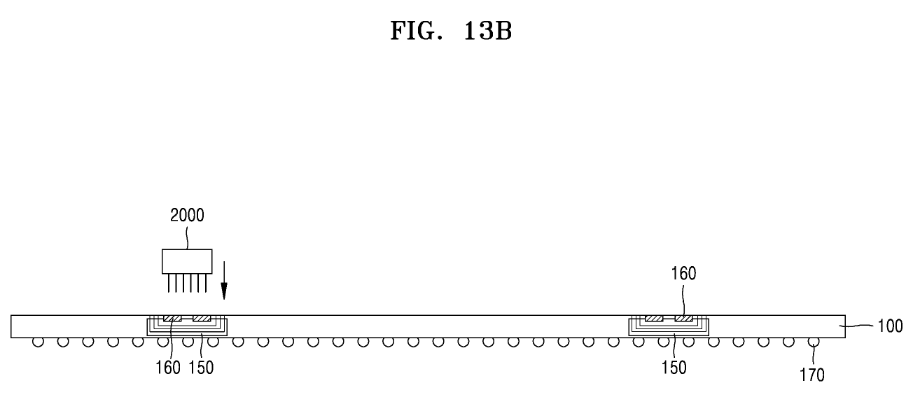

For reference, the second interposer pad 130u2 may be connected to the first semiconductor device 300 and the second semiconductor device 400. Accordingly, the second interposer pad 130u2 may have a relatively small pitch of about several tens of μm. When a test is performed on such a pad having a very small pitch, it may be difficult to perform the test with general test equipment. For example, the pitch of a probe pin of a prober or a test socket of general test equipment is several hundreds of μm. Accordingly, to test a pad having a pitch of several tens of μm, an intermediate medium (PA in FIG. 13A, hereinafter, simply referred to as a “pin adapter”) using a micro-electro-mechanical system (MEMS) process must be used. Using the pin adapter PA may be disadvantageous in terms of cost and time. In contrast, in the case of the interposer 100 of an embodiment, the pitch of the test pad 160 on the Si-bridge 150 may be formed large. Accordingly, the test may be performed through the prober or the test socket of the general test equipment without the pin adapter PA.

The first connection terminal 170 may be disposed on the lower surface of the interposer 100. For example, the first connection terminal 170 may be disposed on the lower surface of the body layer 101. The interposer 100 may be mounted on the package substrate (200 in FIG. 11A) through the first connection terminal 170. The first connection terminal 170 may include, for example, a solder. The solder may include tin (Sn), indium (In), bismuth (Bi), antimony (Sb), Cu, silver (Ag), zinc (Zn), and/or alloys thereof. For example, the solder may include Sn, Sn-Ag, Sn-Au, Sn-Cu, Sn-Bi, Sn-Zn, Sn-Ag-Cu, Sn-Ag-Bi, Sn-Ag-Zn, Sn-Cu-Bi, Sn-Cu-Zn, Sn-Bi-Zn, or the like. In some embodiments, the solder may be referred to as a bump, a solder bump, or the like.

In some embodiments, the first connection terminal 170 may include, for example, a pillar and a solder. The solder may be disposed on the pillar. The pillar may include nickel (Ni), Cu, palladium (Pd), platinum (Pt), gold (Au), or a combination thereof. In the interposer 100 of an embodiment, the pillar may include Cu. However, the material of the pillar is not limited to Cu. In some embodiments, the pillar may function as a pad. When the pillar functions as a pad, the interposer pad 130, e.g., the lower interposer pad 130d, may be omitted.

FIG. 2A shows the test pad 160, the second interposer pad 130u2, and the wire 153 of the left Si-bridge 150L, and FIG. 2B shows the test pad 160, the second interposer pad 130u2, and the wire 153 of the right Si-bridge 150R. The test pad 160 may include a left test pad 160L disposed on the left Si-bridge 150L and a right test pad 160R disposed on the right Si-bridge 150R.

Specifically, in the case of the left Si-bridge 150L in FIG. 2A, the left test pad 160L may be arranged at a central portion of the left Si-bridge 150L in the X direction and at a lower portion of the left Si-bridge 150L in the Y direction. In addition, the second interposer pads 130u2 may be arranged at both outer portions in the X direction. The second interposer pads 130u2 on the left side in the X direction may be connected to the pad of the second semiconductor device 400 through a connection terminal, and the second interposer pad 130u2 on the right side in the X direction may be connected to the pad of the first semiconductor device 300. Accordingly, in FIG. 2A, the dashed line square portion on the left side in the X direction may refer to the second pad area S2-Pad of the second semiconductor device 400 connected to the second interposer pads 130u2 on the left side, and the dashed line square portion on the right in the X directional may refer to the first pad area S1-Pad of the first semiconductor device 300 connected to the second interface pads 130u2.

In the case of the right Si-bridge 150R of FIG. 2B, the right test pad 160R may be arranged at a central portion of the right Si-bridge 150R in the X direction and at an upper portion of the right Si-bridge 150R in the Y direction. In addition, the second interposer pads 130u2 may be arranged at both outer portions in the X direction. The second interposer pad 130u2 on the left side in the X direction may be connected to the pad of the first semiconductor device 300 through a connection terminal, and the second interposer pad 130u2 on the right side in the X direction may be connected to the pad of the second semiconductor device 400. Accordingly, in FIG. 2B, a dashed-line square portion on the left side in the X direction may refer to the first pad area S1-Pad of the first semiconductor device 300 connected to the second interposer pads 130u2 on the left side, and a dashed-line square portion on the right side in the X direction may refer to the second pad area S2-Pad of the second semiconductor device 400 connected to the second interposer pads 130u2 on the right side.

In addition, the wire 153 may include the bridge wire 153a connected between the second interposer pads 130u2, and the test wire 153b connected to the test pad 160. The test wire 153b may also be connected to the second interposer pad 130u2, as shown in FIGS. 3A and 3B.

Specifically, in the left Si-bridge 150L of FIG. 3A, a left first test pad 160L-1 may be connected to the second interposer pad 130u2 through the first test wire 153b-1, and the left second test pad 160L-2 may be connected to the second interposer pad 130u2 through the second test wire 153b-2. In addition, in the right Si-bridge 150R of FIG. 3B, the right first test pad 160R-1 may be connected to the second interposer pad 130u2 through the first test wire 153b-1, and the right second test pad 160R-2 may be connected to the second interposer pad 130u2 through the second test wire 153b-2.

The connection structure between the left test pad 160L and the second interposer pad 130u2 in the left Si-bridge 150L may have a symmetrical relationship, e.g., point symmetrical relationship, with the connection structure between the right test pad 160R and the second interposer pad 130u2 in the right Si-bridge 150R.

In FIGS. 3A and 3B, the hatched 9 second interposer pads 130u2 may be connected to the same net line. The net line may refer to the bridge wire 153a in the Si-bridge 150 corresponding to one signal transmission line. In addition, at least one second interposer pad 130u2 on the first pad area S1-Pad side and at least one second interposer pad 130u2 on the second pad area S2-Pad side may be connected to each other through one net line. The bridge wires 153a commonly connected to one net line may correspond to all the same net lines.

For reference, since two test pads 160 per one net line are needed for testing, twice the number of test pads 160 of the number of the net lines may be needed to test all the net lines of the Si-bridge 150. In general, the Si-bridge 150 may be arranged with one hundred or more net lines. Accordingly, hundreds of test pads 160 and test wires 153b connected thereto may be needed to test all net lines. However, forming all of the test pads 160 and the test wires 153b in the Si-bridge 150 may be disadvantageous in terms of time, cost, or the like and may be impossible in terms of the size of the Si-bridge 150. Accordingly, in the interposer 100 of an embodiment, a selection net line, which is a portion of the net lines, may be extracted, and only the test pad 160 and the test wire 153b corresponding thereto may be formed in the Si-bridge 150.

The extracted selection net line may correspond to net lines of which a defect rate is expected to be high. In one embodiment, the extracted selection net lines may be selected from among the plurality of net lines by a length of the net lines, the number of interposer pads connected to the net lines, or other set criteria. For example, the number of selection net lines may be, for example, around 10% of the total number of net lines. As a specific example, when about 10% of the total net lines are extracted as selection net lines, the selection net lines may be extracted by assigning 30% of the long net lines, 50% of the net lines having a large number of connected second interposer pads 130u2, and 20% of the net lines based on other set criteria. The net line based on other set criteria may correspond to a net line having a high defect rate due to a cause other than the length and the number of connected pads. On the other hand, the ratio of the selection net lines to the total net lines is not limited to about 10% and may be flexibly changed. In addition, the extraction item and the allocation ratio of the selection net lines are not limited to the items and ratios described above.

The interposer 100 of an embodiment may include the Si-bridge 150 therein, and the test pad 160 may be disposed on the Si-bridge 150. Accordingly, the interim test on the Si-bridge 150 may be performed before the semiconductor devices are mounted on the interposer 100. In addition, as the test pad 160 is formed with a wide pitch, the test may be easily and quickly performed through the prober or the test socket of the general test equipment without an intermediate medium, such as a pin adapter. Furthermore, when the first semiconductor device 300 is arranged in the center portion of the upper surface of the interposer 100 and the plurality of second semiconductor devices 400 are arranged on both sides of the first semiconductor device 300, the plurality of Si-bridges 150 corresponding to the second semiconductor devices 400 may be arranged in the interposer 100. In addition, the left Si-bridge 150L on the left side and the right Si-bridge 150R on the right side may have a symmetrical structure with respect to the first semiconductor area SA1 therebetween. For example, the left test pad 160L of the left Si-bridge 150L and the right test pad 160R of the right Si-bridge 150R may be arranged to be point symmetrical to each other. Accordingly, an interim test on the wire state of the Si-bridge 150 may be efficiently performed through a repeated test process. For reference, the first semiconductor device 300 may include a logic device, such as an application specific integrated circuit (ASIC) chip, or the like. In addition, the second semiconductor device 400 may include a memory device, such as a high bandwidth memory (HBM) package. The first semiconductor device 300 and the second semiconductor device 400 are described in more detail with reference to FIGS. 11A and 11B.

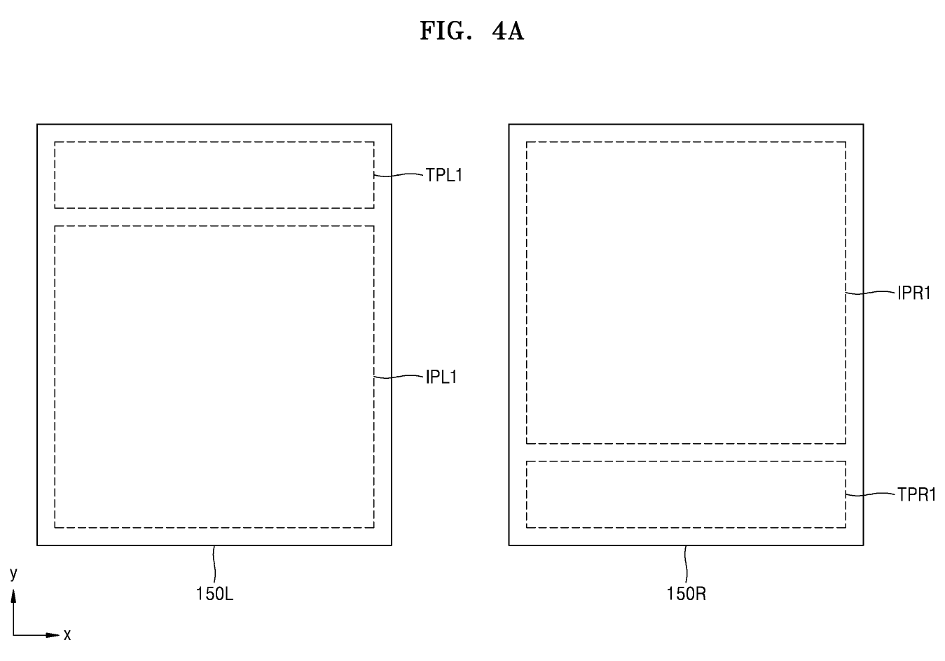

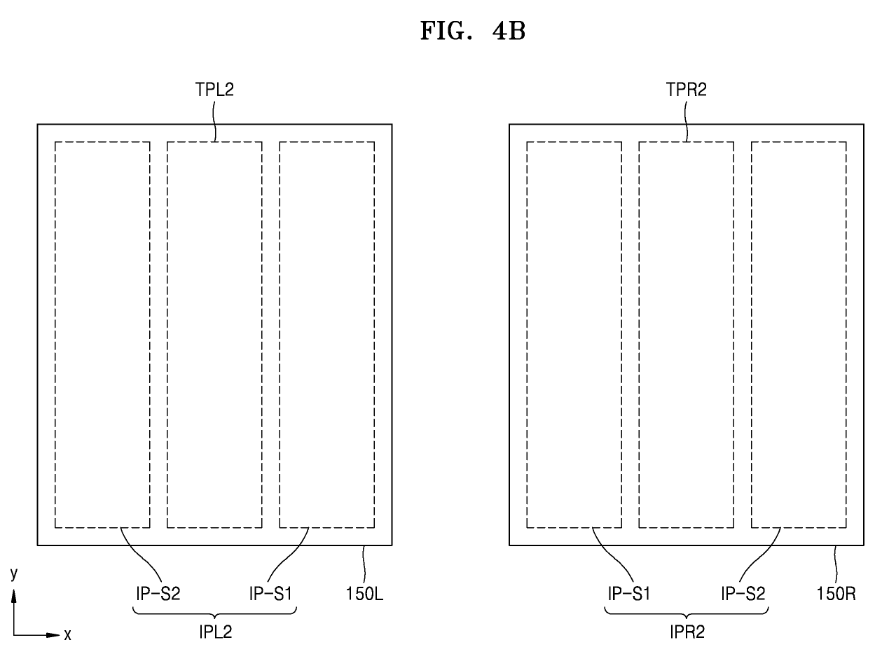

FIGS. 4A and 4B are conceptual views showing the arrangement locations of the test pad and the interposer pad of the Si-bridge in the interposer of FIG. 1A. The description is made with reference to FIGS. 2A and 2B together. Details already described with reference to FIGS. 1A to 3B are briefly described or omitted.

Referring to FIG. 4A, in the interposer 100 of an embodiment, the upper interposer pad 130u may be disposed below or above the Si-bridge 150 in the Y direction, and the test pad 160 may be disposed above or below the Si-bridge 150 in the Y direction. The first semiconductor device 300 and the second semiconductor device 400 may be arranged on both sides of the Si-bridge 150 in the X direction. In addition, the upper interposer pad 130u may correspond to the second interposer pad 130u2 disposed on the Si-bridge 150.

Specifically, in the left Si-bridge 150L, the left test pad 160L may be arranged in an upper left test pad area TPL1 in the Y direction, and the second interposer pad 130u2 may be arranged in a lower left interposer pad area IPL1 in the Y direction. In addition, based on the symmetry relationship, in the right Si-bridge 150R, the right test pad 160R may be arranged in the lower right test pad area TPR1 in the Y direction, and the second interposer pad 130u2 may be arranged in an upper right interposer pad area IPR1 in the Y direction.

Referring to FIG. 4B, in the interposer 100 of an embodiment, the test pads 160 may be arranged at a central portion of the Si-bridge 150 in the X direction, and the upper interposer pads 130u may be arranged at both outer portions of the Si-bridge 150 in the X direction. In the left Si-bridge 150L, the second semiconductor device 400 may be disposed on the left side in the X direction, and the first semiconductor device 300 may be disposed on the right side in the X direction. In addition, in the right Si-bridge 150R, the first semiconductor device 300 may be disposed on the left side in the X direction, and the second semiconductor device 400 may be disposed on the right side in the X direction.

Specifically, in the left Si-bridge 150L, the left test pad 160L may be arranged in the left test pad area TPL2 extending from the center in the X direction toward the Y direction, and the second interposer pad 130u2 may be arranged in the left interposer pad area IPL2 extending from both outer portions in the X direction toward the Y direction. The left interposer pad area IPL2 may include a first interposer pad area IP-S1 connected to the first semiconductor device 300 and a second interposer pad area IP-S2 connected to the second semiconductor device 400. As shown in FIG. 4B, the first interposer pad area IP-S1 may be disposed on the right side in the X direction, and the second interposer pad area IP-S2 may be disposed on the left side in the X direction.

On the other hand, based on the symmetric relationship, in the right Si-bridge 150R, the right test pads 160R may be arranged in a right test pad area TPR2 extending from the center in the X direction toward the Y direction, and the second interposer pads 130u2 may be arranged in the right interposer pad area IPR2 extending from both outer portions in the X direction toward the Y direction. The right interposer pad area IPR2 may also include a first interposer pad area IP-S1 connected to the first semiconductor device 300 and a second interposer pad areas IP-S2 connected to the second semiconductor device 400. As shown in FIG. 4B, the first interposer pad area IP-S1 may be disposed on the left side in the X direction, and the second interposer pad area IP-S2 may be disposed on the right side in the X direction.

Herein, two examples have been shown for arrangement areas of the upper interposer pad 130u and the test pad 160 on the Si-bridge 150 but are not limited thereto. For example, depending on the arrangement positions of the first semiconductor device 300 and the second semiconductor device 400 on the Si-bridge and the positions of the respective pads, the arrangement areas of the test pad 160 and the upper interposer pad 130u on the Si-Bridge 150 may vary.

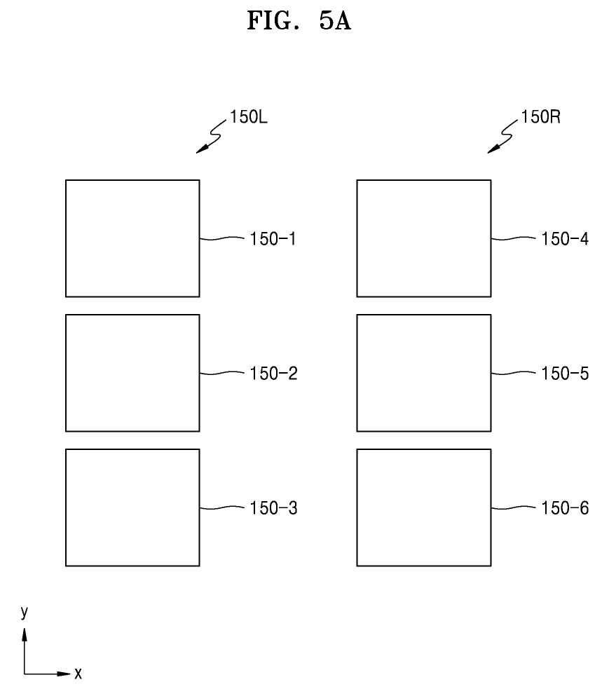

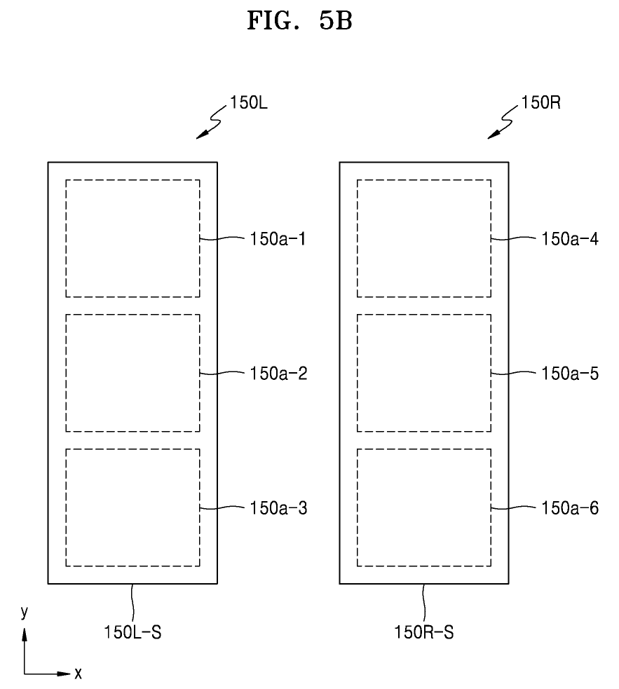

FIGS. 5A and 5B are conceptual views showing the chip structure of the Si-bridge in the interposer of FIG. 1A. Details already described with reference to FIGS. 1A to 4B are briefly described or omitted.

Referring to FIG. 5A, in the interposer 100 of an embodiment, three Si-bridges may each be formed as one semiconductor chip. Specifically, the first to third Si-bridges 150-1 to 150-3 of the left Si-bridge 150L may each be formed as one semiconductor chip and may be arranged in a buried structure inside the body layer 101 and the wiring layer 110 of the interposer 100. In addition, the fourth to sixth Si-bridges 150-4 to 150-6 of the right Si-bridge 150R may each be formed as one semiconductor chip and may be arranged in a buried structure inside the body layer 101 and the wiring layer 110 of the interposer 100. As such, when the Si-bridges are formed as individual semiconductor chips, the body layer 101 and the wiring layer 110 of the interposer 100 may be arranged between the Si-bridges 150 in the Y direction.

Referring to FIG. 5B, in the interposer 100 of an embodiment, all three Si-bridges may be formed in one semiconductor chip. Specifically, the first to third Si-bridges 150a-1 to 150a-3 of the left Si-bridge 150L may be formed together in the left semiconductor chip 150L-S. However, as indicated by the dashed lines, the first to third Si-bridges 150a-1 to 150a-3 may be distinguished by area in the left semiconductor chip 150L-S. The fourth to sixth Si-bridges 150a-4 to 150a-6 of the right Si-bridge 150R may also be formed together in the right semiconductor chip 150R-S. In addition, as indicated by the dashed lines, the fourth to sixth Si-bridges 150a-4 to 150a-6 may be distinguished by area in the right semiconductor chip 150R-S.

The left semiconductor chip 150L-S and the right semiconductor chip 150R-S may be arranged in a buried structure inside the body layer 101 and the wiring layer 110 of the interposer 100, respectively. As such, when three Si-bridges 150 are formed in one semiconductor chip, an Si layer of the semiconductor chip or an insulating layer separately formed in the semiconductor chip may be arranged between the Si-bridges 150 in the Y direction.

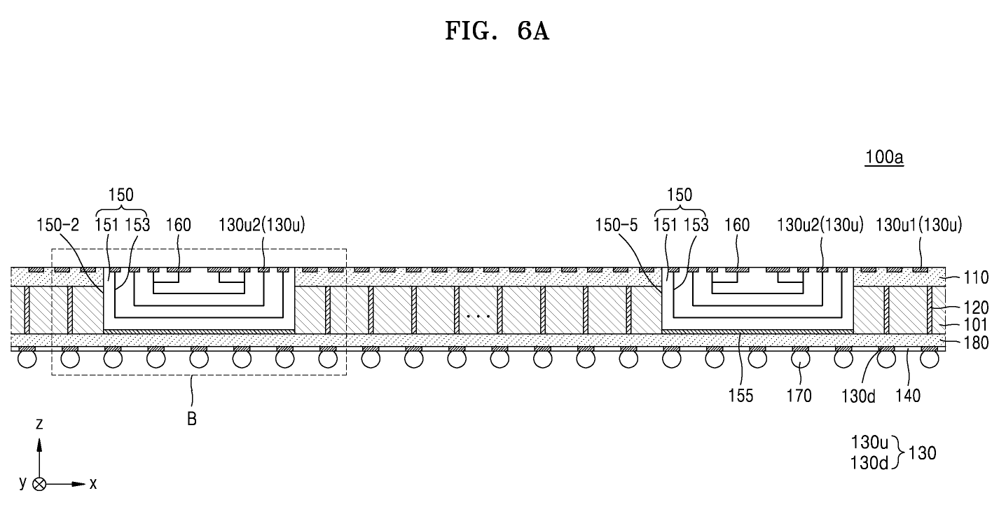

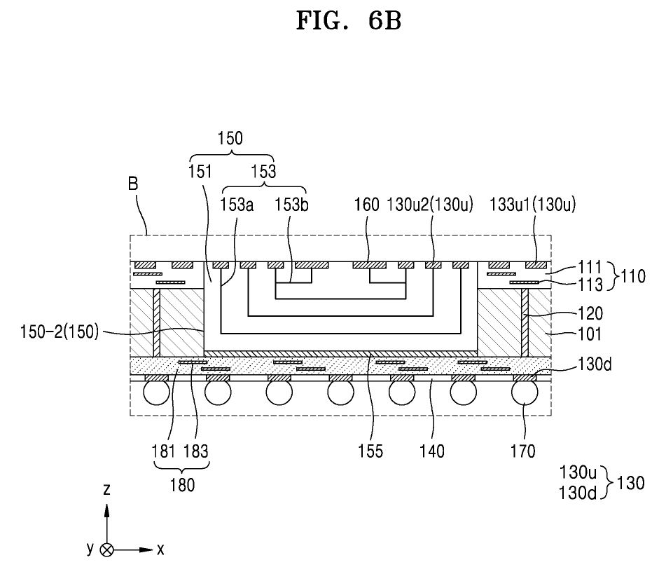

FIGS. 6A and 6B are a cross-sectional view and an enlarged view of an interposer according to an embodiment, in which the cross-sectional view of FIG. 6A corresponds to the cross-sectional view of FIG. 1B and the cross-sectional view of FIG. 6B is an enlarged cross-sectional view of portion B of FIG. 6A. The descriptions are made with reference to FIGS. 1A to 1C together. Details already described with reference to FIGS. 1A to 5B are briefly described or omitted.

Referring to FIGS. 6A and 6B, an interposer 100a of an embodiment may be different from the interposer 100 of FIG. 1B in that the interposer 100a further includes a lower wiring layer 180. Specifically, the interposer 100a of an embodiment may include the body layer 101, the wiring layer 110, the through posts 120, the interposer pads 130, the protective layer 140, the Si-bridges 150, the test pads 160, the first connection terminals 170, and the lower wiring layer 180. The body layer 101, the wiring layer 110, the through posts 120, the interposer pads 130, the protective layer 140, the Si-bridges 150, the test pads 160, and the first connection terminals 170 are the same as those described with reference to the interposer 100 in FIG. 1B.

The lower wiring layer 180 may be disposed on the lower surface of the body layer 101. The lower wiring layer 180 may be referred to as a lower RDL, a rear wiring layer, and a rear RDL. The lower wiring layer 180 may include a lower interlayer insulating layer 181 and lower wiring lines 183, and lower wiring lines of another layer may be connected to each other through a vertical via. The lower interlayer insulating layer 181, the lower wiring lines 183, and the vertical via of the lower wiring layer 180 are the same as the interlayer insulating layer 111, the wiring lines 113, and the vertical via of the wiring layer 110 described above.

As the lower wiring layer 180 is disposed on the lower surface of the body layer 101, the lower portion of the through post 120 may be connected to the lower wiring line 183 of the lower wiring layer 180. For example, the through post 120 may have a structure extending through the body layer 101 between the wiring layer 110 and the lower wiring layer 180. In addition, the lower interposer pads 130d and the protective layer 140 may be disposed on the lower surface of the lower wiring layer 180. The lower interposer pad 130d may be connected to the lower wiring line 183 of the lower wiring layer 180. Accordingly, the lower interposer pad 130d may be connected to the post 120 through the lower wiring layer 180.

On the other hand, the Si-bridge 150 may be arranged inside the body layer 101 and the wiring layer 110, while being disposed on the lower wiring layer 180. For example, the Si-bridge 150 may be adhered and secured to the lower wiring layer 180 through the adhesive layer 155. In some embodiments, the body layer 101 may be maintained thin between the Si-bridge 150 and the lower wiring layer 180. In such a case, the Si-bridge 150 may be adhered and fixed to the body layer 101 through the adhesive layer 155. In some embodiments, the adhesive layer 155 may be omitted.

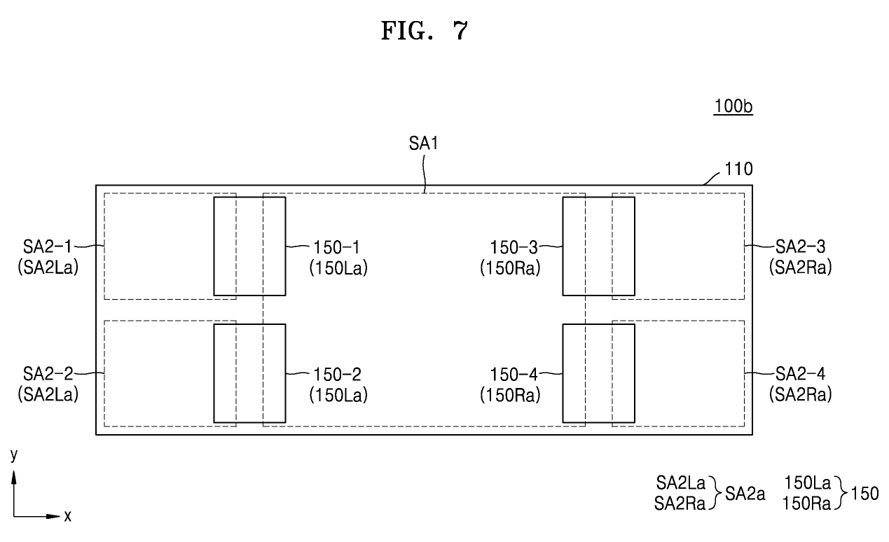

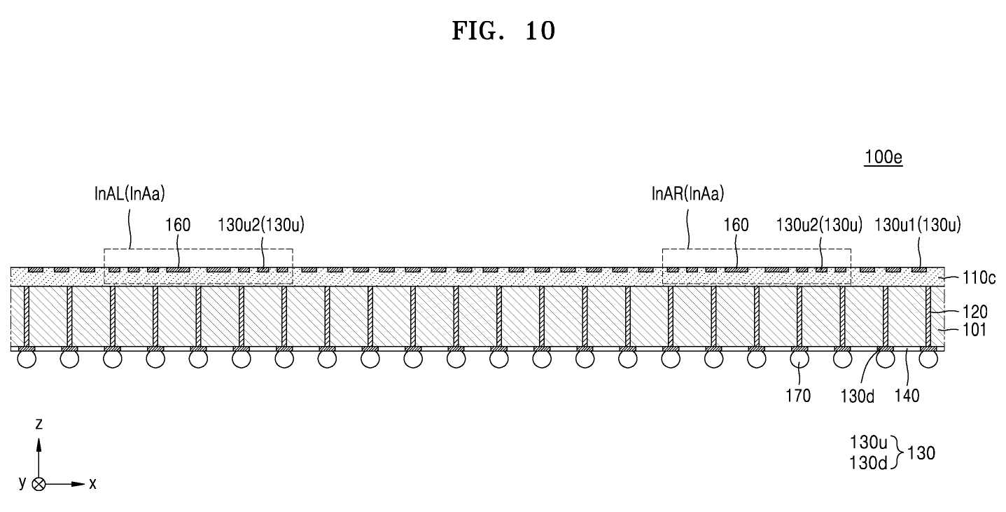

FIGS. 7 to 10 are plan views and a cross-sectional view of the interposer according to embodiments. Each of the plan views of FIGS. 7A to 9 corresponds to the plan view of FIG. 1A, and the cross-sectional view of FIG. 10 corresponds to the cross-sectional view of FIG. 1B. The description will be made with reference to FIGS. 1A to 1C together. Details described with reference to FIGS. 1A to 6B are briefly described or omitted.

Referring to FIG. 7, an interposer 100b of an embodiment may be different from the interposer 100 of FIG. 1A in that the number of Si-bridges 150 and the number of mounting areas of the second semiconductor area SA2a are different from those of the interposer 100 of FIG. 1A. Specifically, the cross-sectional structure of the interposer 100b of an embodiment may be substantially the same as the cross-sectional structure of the interposer 100 of FIG. 1B. Accordingly, the interposer 100b of an embodiment may also include the body layer 101, the wiring layer 110, the through posts 120, the interposer pads 130, the protective layer 140, the Si-bridges 150, the test pads 160, and the first connection terminals 170.

In the case of the interposer 100b of an embodiment, one first semiconductor device 300 and four second semiconductor devices 400 may be mounted. Accordingly, the second semiconductor area SA2a may include four mounting areas, and four Si-bridges 150 may be arranged in the interposer 100b. In addition, the width of the interposer 100b in the Y direction may be less than the width of the interposer 100 of FIG. 1B. However, the width of the interposer 100b is not limited thereto.

Specifically, the first semiconductor area SA1 may be arranged at a central portion in the X direction and the second semiconductor areas SA2a may be disposed on both sides of the first semiconductor area SA1 in the X direction. In addition, the second semiconductor areas SA2a may include a left second semiconductor area SA2La and a right second semiconductor area SA2Ra. The left second semiconductor area SA2La may include a first mounting area SA2-1 and a second mounting area SA2-2, and the right second semiconductor area SA2Ra may include a third mounting area SA2-3 and a fourth mounting area SA2-4.

The Si-bridge 150 may include a left S-bridge 150La and a right S-bridge 15Ra respectively corresponding to the left second semiconductor area SA2La and the right second semiconductor area SA2Ra. The left S-bridge 150La may include the first Si-bridge 150-1 and the second Si-bridge 150-2, and the right S-bridge 150Ra may include the third Si-bridge 150-3 and the fourth Si-bridge 150-4.

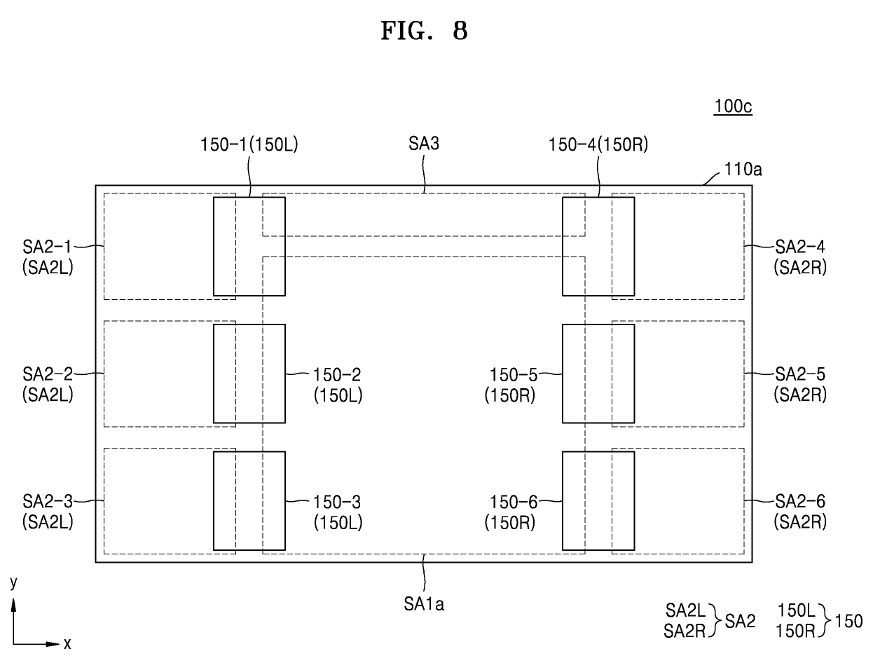

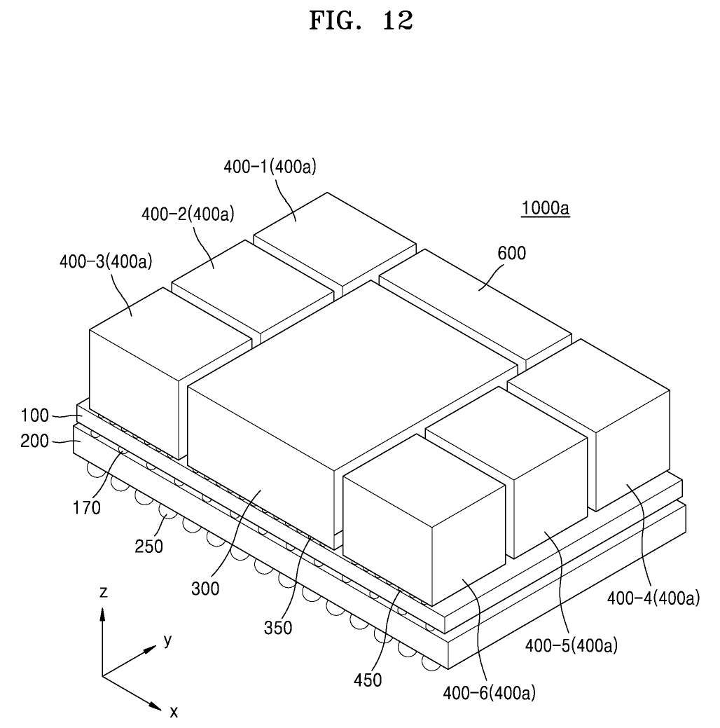

Referring to FIG. 8, an interposer 100c of an embodiment may be different from the interposer 100 of FIG. 1A in that the interposer 100c further includes a third semiconductor area SA3. Specifically, the cross-sectional structure of the interposer 100c of an embodiment may be substantially the same as the cross-sectional structure of the interposer 100 of FIG. 1B. Accordingly, the interposer 100c of an embodiment may also include the body layer 101, a wiring layer 110a, the through posts 120, the interposer pads 130, the protective layer 140, the Si-bridges 150, the test pads 160, and the first connection terminals 170. However, the wiring layer 110a may further include wiring lines for connecting the first semiconductor device 300 to a chiplet (600 in FIG. 12).

In the case of the interposer 100c of an embodiment, one first semiconductor device 300 and six second semiconductor devices 400 may be mounted in the same manner as the interposer 100 of FIG. 1A. Accordingly, the second semiconductor area SA2 may include six mounting areas and six Si-bridges 150 may be arranged in the interposer 100c. In addition, the arrangement positions of the second semiconductor area SA2 and the Si-bridge 150 may be substantially the same as those in the interposer 100 of FIG. 1A. However, as the third semiconductor area SA3 is disposed above a first semiconductor area SA1a in the Y direction, the width of the first semiconductor area SA1a in the Y-direction may be less than the width of the first semiconductor area SA1 of the interposer 100 of FIG. 1A.

The third semiconductor area SA3 may be arranged above the first semiconductor area SA1a in the Y direction in the central portion of the interposer 100c in the X direction. The third semiconductor area SA3 may include an area where the chiplet 600 is mounted. For reference, a chiplet structure, which is a concept opposite to a system on chip (SoC) structure, may have a structure in which a logic chip is divided into separate chips for each function and the chips are connected to each other. For example, in the chiplet structure, logic chips, such as a central processing unit (CPU) chip, a graphics processing unit (GPU), an input/output (I/O) chip, a communication modem chip, and other functional chips may be individually formed and connected to each other. The chiplet structure may overcome the performance limitations of a single chip of the SoC structure.

In the case of the interposer 100c of FIG. 8, most of the logic devices may be included in the first semiconductor device 300 in the SoC structure and mounted in the first semiconductor area SA1a, and I/O logic devices or communication logic devices may be formed of the chiplet 600, such as the I/O chip or the communication modem chip, and mounted on the third semiconductor area SA3. In addition, the first semiconductor device 300 of the first semiconductor area SA1a and the chiplet 600 of the third semiconductor area SA3 may be connected through the wiring lines 113 of the wiring layer 110 of the interposer 100.

In addition, the SoC structure may have a structure in which various functional logic devices are integrated and systemized in one chip. Accordingly, in the case of the semiconductor device having the SoC structure, arithmetic functions, data storage, analog and digital signal conversion, or the like may be performed in one chip. For example, when the first semiconductor device 300 of FIG. 11A has the SoC structure, the first semiconductor device 300 may include a CPU area, a GPU area, an I/O area, a communication area, and other areas therein.

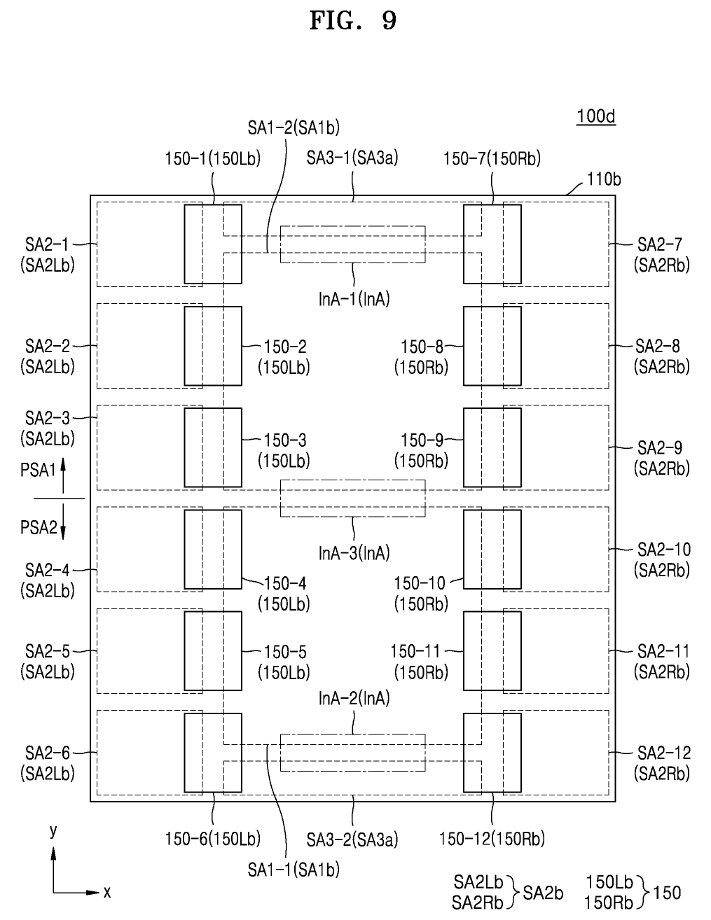

Referring to FIG. 9, an interposer 100d of an embodiment may be different from the interposer 100 of FIG. 1A in that the number of Si-bridges 150 and the number of mounting areas are different from those of the interposer 100 of FIG. 1A of the second semiconductor area SA2a and the interposer 100d further includes third semiconductor areas SA3a. Specifically, the cross-sectional structure of the interposer 100d of an embodiment may be substantially the same as the cross-sectional structure of the interposer 100 of FIG. 1B. Accordingly, the interposer 100d of an embodiment may also include the body layer 101, a wiring layer 110b, the through posts 120, the interposer pads 130, the protective layer 140, the Si-bridges 150, the test pads 160, and the first connection terminals 170.

In the case of the interposer 100d of an embodiment, two first semiconductor devices 300 and twelve second semiconductor devices 400 may be mounted on the interposer 100d. Accordingly, two first semiconductor areas SA1b may be arranged, the second semiconductor areas SA2b may include 12 mounting areas, and 12 Si-bridges 150 may be arranged in the interposer 100d. In addition, the width of the interposer 100d in the Y direction may be about twice the width of interposer 100 of FIG. 1B. However, the width of the interposer 100d is not limited thereto.

Specifically, the first semiconductor areas SA1b may be allocated to the central portion in the X direction, and the second semiconductor areas SA2b may be allocated to both sides of the first semiconductor areas SA1b in the X direction. The first semiconductor area SA1b may include an upper first semiconductor area SA1-1 assigned to an upper portion of the first semiconductor area SA1b in the Y direction and a lower first semiconductor area SA2-2 assigned to a lower portion of the first semiconductor area SA1b. In addition, the second semiconductor area SA2b may include left second semiconductor areas SA2Lb and right second semiconductor areas SA2Rb. The left second semiconductor areas SA2Lb may include six mounting areas SA2-1 to SA2-6, and the right second semiconductor areas SA2Rb may include six mounting areas SA2-7 to SA2-12.

On the other hand, a third semiconductor area SA3a may be allocated to an upper portion and a lower portion of the first semiconductor area SA1b in the Y direction. The third semiconductor areas SA3a may include an upper third semiconductor area SA3-1 assigned to an upper portion of the interposer 100d in the Y direction and a lower third semiconductor area SA3-2 assigned to a lower portion of the interposer 100d. The structures of the upper first semiconductor area SA1-1 and the upper third semiconductor area SA3-1 may be substantially the same as the structures of the first semiconductor area SA1a and the third semiconductor area SA3 of the interposer 100c of FIG. 8. In addition, the structures of the lower first semiconductor area SA1-2 and the lower third semiconductor area SA3-2 are symmetrical, e.g., point-symmetrical, with the structures of the upper first semiconductor area SA1-1 and the upper third semiconductor area SA3-1. Accordingly, the structure of the first semiconductor area SA1a and the structure of the third semiconductor area SA3, in which the interposer 100c of FIG. 8 is rotated by 180°, may be substantially the same.

For reference, two first semiconductor devices 300, 12 second semiconductor devices 400, and two chiplets 600 may be mounted on the interposer 100d of an embodiment to configure a semiconductor package (1000a in FIG. 12). In the semiconductor package 1000a, the two first semiconductor devices 300 may be the same in structure and function. However, the two first semiconductor devices 300 may be mounted on the interposer 100d in a symmetrical structure. In addition, an upper first half portion in the Y direction of the interposer 100d, one first semiconductor device 300 mounted on the first half portion of the interposer 100d, six second semiconductor devices 400 connected thereto, and one chiplet 600 may constitute an upper package. In addition, a lower second half portion in the Y direction of the interposer 100d, one first semiconductor device 300 mounted on the second half portion of the interposer 100d, six second semiconductor devices 400 connected thereto, and one chiplet 600 may constitute a lower package.

With respect to the semiconductor package 1000a, the upper first semiconductor area SA1-1 of the first half portion of the interposer 100d, six mounting areas SA2-1 to SA2-3 and SA2-7 to SA2-9 of the upper second semiconductor area SA2b in the Y direction corresponding thereto, and the upper third semiconductor area SA3-1 may constitute an upper package area PSA1. In addition, the lower first semiconductor area SA1-2 of the second half portion of the interposer 100d, six mounting areas SA2-4 to SA2-6 and SA2-10 to SA2-12 of the lower second semiconductor area SA2b in the Y direction corresponding thereto, and the lower third semiconductor area SA3-2 may constitute a lower package area PSA2.

The structure of the upper package area PSA1 may be substantially the same as the structure of the interposer 100c in FIG. 8, and the structure of the lower package area PSA2 may be substantially the same as a structure obtained by rotating the interposer 100c in FIG. 8 by 180°. Accordingly, a left Si-bridge 150Lb and a right Si-bridge 150Rb of the upper package area PSA1 may have a symmetrical structure, and a left Si-bridge 150Lb and a right Si-bridge 150Rb of the lower package area PSA2 may have a symmetrical structure.

The wiring layer 110b of the interposer 100d may include connection areas InA for connecting the first semiconductor device 300 to the chiplet 600. The connection areas InA may be arranged to overlap a portion of the first semiconductor area SA1b and a portion of the third semiconductor area SA3a, as indicated by the squares of the dashed-dotted lines in FIG. 9. The connection areas InA may include a first connection area InA-1 between the upper first semiconductor area SA1-1 and the upper third semiconductor area SA3-1, and a second connection area InA-2 between the lower first semiconductor area SA1-2 and the lower third semiconductor area SA3-2. Due to the symmetrical structure between the upper package area PSA1 and the lower package area PSA2, the first connection area InA-1 and the second connection area InA-2 may have a symmetrical structure. On the other hand, in some embodiments, the connection areas InA may include a third connection area InA-3 between the upper first semiconductor area SA1-1 and the lower first semiconductor area SA1-2. The third connection area InA-3 may connect two first semiconductor devices 300.

In some embodiments, Si-bridges may be arranged instead of the connection areas InA. In such a case, the first semiconductor area SA1b may be connected to the third semiconductor area SA3a via the Si-bridge.

The structure in which the first semiconductor area, the second semiconductor area, and the Si-bridge are disposed on the interposer has been described corresponding to a structure in which four or six second semiconductor devices are mounted on the interposer for each first semiconductor device 300, but the interposer of an embodiment is not limited thereto. For example, the first semiconductor area, the second semiconductor area, and the Si-bridge may be disposed on the interposer corresponding to a structure in which various numbers of second semiconductor devices 400 are mounted, such as two or eight semiconductor devices 400, on the interposer for each first semiconductor device 300.

Referring to FIG. 10, an interposer 100e according to one embodiment may differ from the interposer 100 of FIG. 1B in that the interposer 100e does not include a Si-bridge, and a wiring layer 110c thereof includes a second connection area InAa. Specifically, the interposer 100e of an embodiment may include the body layer 101, the wiring layer 110c, the through posts 120, the interposer pads 130, the protective layer 140, the test pads 160, and the first connection terminals 170. The body layer 101, the through posts 120, the interposer pads 130, the protective layer 140, the test pads 160, and the first connection terminals 170 are the same as those described with reference to the interposer 100 of FIG. 1B. However, the interposer 100e of an embodiment may simply correspond to a PLP interposer, an RDL interposer, or the like. On the other hand, since the interposer 100e does not include the Si-bridge, a trench may not be formed in the body layer 101 and the wiring layer 110c.

In the interposer 100e of an embodiment, the wiring layer 110c may include the second connection area InAa. The second connection area InAa may serve a similar function as the Si-bridge 150 of the interposer 100 shown in FIG. 1B. For example, when the first semiconductor device 300 and the second semiconductor device 400 are mounted on the interposer 100e, the first semiconductor device 300 and the second semiconductor devices 400 may be connected through wiring lines 113 of the second connection area InAa.

The second connection area InAa may include a left second connection area InAL and a right second connection area InAR, similarly to the Si-bridge 150 shown in FIG. 1B. In addition, the second interposer pads 130u2 and the test pads 160 may be disposed on the second connection area InAa. An interim test on the wiring line condition in the second connection area InAa of the interposer 100e may be conducted via the test pad 160.

FIGS. 11A and 11B are a perspective view and a cross-sectional view of a semiconductor package including the interposer, according to an embodiment. FIG. 11B is a cross-sectional view taken along line II-II′ in FIG. 11A. The descriptions are made with reference to FIGS. 1A to 1C together, and details described with reference to FIGS. 1A and 10 are briefly described or omitted.

Referring to FIGS. 11A and 11B, a semiconductor package 1000 of an embodiment may include the interposer 100, the package substrate 200, the first semiconductor device 300, the second semiconductor devices 400, and an external sealant 500. For reference, the external sealant 500 is omitted and is not shown in FIG. 11A. The interposer 100 may correspond to the interposer 100 of FIG. 1B. However, the interposer 100 is not limited thereto. For example, instead of the interposer 100 of FIG. 1B, the interposer 100a or 100e of FIG. 6A or 10 may be applied to the semiconductor package 1000 of an embodiment.

The interposer 100 may be mounted on the package substrate 200 via the first connection terminals 170. The interposer 100 may be arranged between the package substrate 200 and the first semiconductor device 300 and between the package substrate 200 and the second semiconductor device 400. For example, the first semiconductor device 300 and the second semiconductor devices 400 are disposed on the interposer 100, and the interposer 100 may mediate signal transmission between the first semiconductor device 300 and the second semiconductor devices 400. In addition, the interposer 100 may mediate transmission of signals, power, or the like between the first semiconductor device 300 and the package substrate 200 and between the second semiconductor devices 400 and the package substrate 200.

In addition, an underfill 175 may fill the gap between the interposer 100 and the package substrate 200 and the gap between the first connection terminals 170. In other embodiments, the underfill 175 may be replaced with an adhesive layer or an adhesive film. In other aspects, the descriptions of the interposer 100 are the same as those described with reference to the interposer 100 in FIG. 1B.

The package substrate 200 may include, for example, a ceramic substrate, a printed circuit board (PCB), an organic substrate, an interposer substrate, or the like. In some embodiments, the package substrate 200 may include an active wafer, such as a Si wafer. In the semiconductor package 1000 of an embodiment, the package substrate 200 may include the PCB. However, the package substrate 200 is not limited to the PCB.

The package substrate 200 may include a substrate body layer and a protective layer. The substrate body layer may constitute the body of the package substrate 200 and may include a wiring layer therein. For example, when the package substrate 200 is the PCB, the substrate body layer may include a core layer 201 and a wiring layer 210. The core layer 201 may include, for example, resin and glass fibers, such as FR4. In addition, the core layer 201 may include bismaleimide-triazine (BT) resin, polycarbonate (PC) resin, build up films, such as Ajinomoto build-up film (ABF), or other laminate resins. In some embodiments, the core layer may be omitted.

The wiring layer 210 may be divided into an upper wiring layer 210a and a lower wiring layer 210b with the core layer 201 interposed therebetween. The upper wiring layer 210a and the lower wiring layer 210b may each include multiple layers of wires. The number of layers of wires in the upper wiring layer 210a may be the same as or different from the number of layers of wires in the lower wiring layer 210b. In the semiconductor package 1000 of an embodiment, the wiring layer may include 8 to 14 layers of wires. However, the number of layers of wires in the wiring layer is not limited to the above numerical range.

The wiring layer may include multiple layers of wires, an interlayer insulating layer that insulates between the wires, and a vertical via that connects the wires of different layers to each other. The wires and the vertical via may include, for example, Cu. However, the material of the wires and the vertical via is not limited to Cu. The interlayer insulating layer may include, for example, prepreg (PPG). The material of the interlayer insulating layer is not limited to PPG.

In some embodiments, the package substrate 200 may include a redistribution substrate. In such a case, the substrate body layer does not include a separate core layer and may include an interlayer insulating layer of a PID resin and multi-layer wires.

The protective layer may be formed on the upper and lower surfaces of the substrate body layer. The protective layer may include, for example, a solder resist (SR). However, the material of the protective layer is not limited to SR.

External connection terminals 250 may be disposed on a lower surface of the package substrate 200. The external connection terminals 250 may connect the semiconductor package 1000 to a package substrate of an external system, a main board of an electronic device, such as a mobile device, or the like. The external connection terminals 250 may include at least one of a conductive material, for example, a solder, Sn, Ag, Cu, and aluminum (Al). However, the material of the external connection terminals 250 is not limited thereto.

The first semiconductor device 300 may be mounted on the interposer 100 via the second connection terminals 350. As shown in FIGS. 11A and 11B, the first semiconductor device 300 may be arranged in the central portion of the interposer 100 in the X direction.

The first semiconductor device 300 may have a chip or a package structure. In the semiconductor package 1000 of an embodiment, the first semiconductor device 300 may have a chip structure. For example, the first semiconductor device 300 may include a logic chip. The first semiconductor device 300 may include a plurality of logic devices therein. For example, the logic devices include an AND, a NAND, an OR, a NOR, exclusive OR (XOR), an exclusive NOR (XNOR), an inverter (INV), an adder (ADD), a delay (DLY), a filter (FIL), a multiplexer (MXT/MXIT), An OAI (OR/AND/INVERTER), AO (AND/OR), an AOI (AND/OR/INVERTER), a D flip-flop, a reset flip-flop, a master-slave flip-flop, a latch, a counter, or buffer devices. The logic devices may perform various signal processing, such as analog signal processing, analog-to-digital (A/D) conversion, and control. The first semiconductor device 300 may be referred to as a CPU chip, a micro-processor unit (MPU) chip, a graphics processing unit (GPU) chips, a neural processing unit (NPU) chip, a system-on-glass (SOG) chip, an application specific integrated circuit (ASIC) chip, an application processor (AP) chip, a control chip, or the like, depending on the function of the first semiconductor device 300.

The first semiconductor device 300 having a chip structure may have a SoC structure or may have a chiplet structure. For example, in the semiconductor package 1000 of an embodiment, the first semiconductor device 300 may have the SoC structure. However, the structure of the first semiconductor device 300 is not limited to the SoC structure. On the other hand, the first semiconductor device 300 may include devices supporting communication together. However, in some embodiments, devices supporting communication may be separately provided as another chip, for example, a modem chip, and may be disposed on the interposer 100 in a structure coupled to the first semiconductor device 300.

The first semiconductor device 300 may include a chip body and an active layer. The chip body constitutes the body of the first semiconductor device 300 and may include Si. However, the material of the chip body is not limited to Si. For example, the chip body may include other semiconductor materials, such as germanium (Ge), Si-Ge, or the like, or Group III-V compounds, such as GaP, GaAs, GaSb, or the like. In addition, in some embodiments, the chip body may include a silicon-on-insulator (SOI) substrate, or a germanium-on-insulator (GOI) substrate.

The active layer may be disposed below the chip body and may include a first integrated circuit layer and a first wiring layer. The first integrated circuit layer may include a number of integrated devices. The first integrated device may include, for example, a transistor. However, the first integrated device is not limited to the transistor. The first wiring layer may be disposed below the first integrated circuit layer. The first wiring layer may include an interlayer insulating layer, wires, and a chip pad. The wires may be arranged in two or more layers, and wires of different layers may be connected to each other through the vertical via.

The lower surface of the first semiconductor device 300 may be a front side that is an active surface, and the upper surface of the first semiconductor device 300 may be a back side that is an inactive surface. In other words, the lower surface of the wiring layer may correspond to the front side of the first semiconductor device 300, and the upper surface of the chip body may correspond to the back side of the first semiconductor device 300.

The second semiconductor devices 400 may be mounted on the interposer 100 via third connection terminals 450. As shown in FIGS. 11A and 11B, the second semiconductor devices 400 (e.g., 400-1, 400-2, 400-3 and 400-4 as shown in FIG. 11A) may be disposed on the interposer 100 on both sides of the first semiconductor device 300 in the X direction.

In the semiconductor package 1000 of an embodiment, four second semiconductor devices 400 may be disposed on the interposer 100. For example, two second semiconductor devices 400 may be disposed on the interposer 100 on each of both sides of the first semiconductor device 300. However, in the semiconductor package 1000 of an embodiment, the number of second semiconductor devices 400 is not limited to four. For example, one to three or five or more second semiconductor devices 400 may be disposed on the interposer 100.

In the semiconductor package 1000 of an embodiment, the second semiconductor device 400 may include an HBM package. Specifically, the second semiconductor device 400 may include a base chip 410, a plurality of core chips 420 stacked on the base chip 410, and an internal sealant 440. In addition, the base chip 410 and the core chips 420 may include through electrodes 430 therein. However, the uppermost core chip 420 of the core chips 420 may not include the through electrodes 430.

The base chip 410 may include logic devices. Accordingly, the base chip 410 may be a logic chip. The base chip 410 may be disposed below the core chips 420 and may integrate and transmit signals of the core chips 420 to the outside and also transmit the signals and the power source from the outside to the core chips 420. Accordingly, the base chip 410 may be referred to as a buffer chip or a control chip. In addition, each of the core chips 420 may include a memory chip. For example, each of the core chips 420 may be a dynamic random-access memory (DRAM) chip. Moreover, the core chips 420 may be stacked on the base chip 410 through pad-to-pad bonding, hybrid copper bonding (HCB), bonding using a connection terminal, bonding using an anisotropic conductive film (ACF), or the like. In FIG. 11B, 12 core chips 420 are stacked on the base chip 410, but the number of core chips 420 is not limited to 12. For example, the number of core chips 420 may be 11 or less, or 13 or more, stacked on the base chip 410.

The third connection terminals 450 may be disposed on the lower surface of the base chip 410. Accordingly, the second semiconductor device 400 of the HBM package may be mounted on the interposer 100 via the third connection terminals 450. The core chips 420 on the base chip 410 may be sealed by the internal sealant 440. However, the upper surface of the uppermost core chip 420 of the core chips 420 may not be covered by the internal sealant 440. However, in other embodiments, the upper surface of the uppermost core chip 420 may be covered by the internal sealant 440.

In addition, in the semiconductor package 1000 of an embodiment, the second semiconductor device 400 is not limited to the HBM package. For example, the second semiconductor device 400 may have a single chip structure or a general package structure. For a general package structure, the second semiconductor device 400 may include an upper package substrate and a plurality of memory chips stacked on the upper package substrate. In addition, the memory chips may be stacked on the upper package substrate via a bonding wire or stacked on the upper package substrate via a bump and a TSV. On the other hand, the memory devices may include volatile memory devices, such as DRAM, static random-access memory (SRAM), or the like, or non-volatile memory devices, such as flash memory or the like.

The external sealant 500 may cover and seal the first semiconductor device 300 and the second semiconductor device 400 on the interposer 100. As shown in FIG. 11B, the external sealant 500 may not cover the upper surfaces of the first semiconductor device 300 and the second semiconductor device 400. However, in other embodiments, the external sealant 500 may cover the upper surface of at least one of the first semiconductor device 300 and the second semiconductor device 400. On the other hand, although not shown, the semiconductor package 1000 of an embodiment may further include a second external sealant that covers and seals the external sealant 500 and the interposer 100 on the package substrate 200.

For reference, the structure of the semiconductor package 1000 as in an embodiment is referred to as a 2.3D or 2.xD package structure, in which the 2.3D or 2.xD package structure may be a relative concept to a 3D package structure in which all semiconductor chips are stacked together and there is no interposer. Both the 2.3D or 2.xD package structure and the 3D package structure may be included in a system in package (SIP) structure.

FIG. 12 is a perspective view of the semiconductor package including the interposer, according to an embodiment. The descriptions are made with reference to FIG. 8, and the details described with reference to FIG. 1A to FIG. 11B are briefly described or omitted.

Referring to FIG. 12, the semiconductor package 1000a of an embodiment may be different from the semiconductor package 1000 of FIG. 11A in that the number of second semiconductor devices 400a is different from those of the semiconductor package 1000 and the semiconductor package 1000a further includes the chiplet 600. Specifically, the semiconductor package 1000a may include the interposer 100, the package substrate 200, the first semiconductor device 300, second semiconductor devices 400a, the external sealant, and the chiplet 600. For reference, the external sealant is omitted and is not shown in FIG. 12. The interposer 100, the package substrate 200, the first semiconductor device 300, and the sealant are the same as those described with reference to the semiconductor package 1000 of FIG. 11A.

The second semiconductor devices 400a may be mounted on the interposer 100 via the third connection terminals 450. As shown in FIG. 12, the second semiconductor devices 400a may be disposed on the interposer 100 on both sides of the first semiconductor device 300 in the X direction.

In the semiconductor package 1000a of an embodiment, six second semiconductor devices 400a (e.g., 400-1, 400-2, 400-3, 400-4, 400-5, and 400-6 as shown in FIG. 12) may be disposed on the interposer 100. For example, three second semiconductor devices 400a may be disposed on the interposer 100 on each of both sides of the first semiconductor device 300. However, in the semiconductor package 1000 of an embodiment, the number of second semiconductor devices 400a is not limited to six. For example, one to five or seven or more second semiconductor devices 400a may be disposed on the interposer 100.

The chiplet 600 on the interposer 100 may be arranged in the central portion of the semiconductor package 1000a in the X direction and above the first semiconductor device 300 in the Y direction. For example, the chiplet 600 may include logic devices that support the operation of the first semiconductor device 300. For example, the chiplet 600 may include an I/O chip, a modem chip, or the like. However, the type of the chiplet 600 is not limited thereto. The chiplet 600 may be connected to the first semiconductor device 300 through a connection area of the wiring layer 110 of the interposer 100. In some embodiments, the Si-bridge may be arranged in the interposer 100 instead of the connection area, and the chiplet 600 and the first semiconductor device 300 may be connected through the Si-bridge.

FIGS. 13A and 13B are conceptual diagrams showing differences between the testing method for the interposer of a comparative example and the testing method for the interposer of an embodiment.

Referring to FIGS. 13A and 13B, in the case of the testing method for the interposer of the comparative example of FIG. 13A, an interposer InP may be tested through a prober PB or a test socket TS of test equipment TA, and an intermediate medium, such as a pin adapter PA, corresponding to a first connection terminal S1 of the interposer InP may be required. Accordingly, the manufacturing difficulty of the test equipment may increase and may be disadvantageous in terms of cost. In addition, when the size of the interposer InP increases, the cost problem may also increase. On the other hand, in the case of the testing method for the interposer InP of the comparative example, the test may be performed after a first semiconductor device CH1 and a second semiconductor device CH2 are mounted thereon. Accordingly, when a defect in the interposer InP, for example, a defect in Si-bridge Si-Bg, is detected, an enormous loss may be caused. For reference, in FIG. 13A, S2 is a second connection terminal and S3 is a third connection terminal.

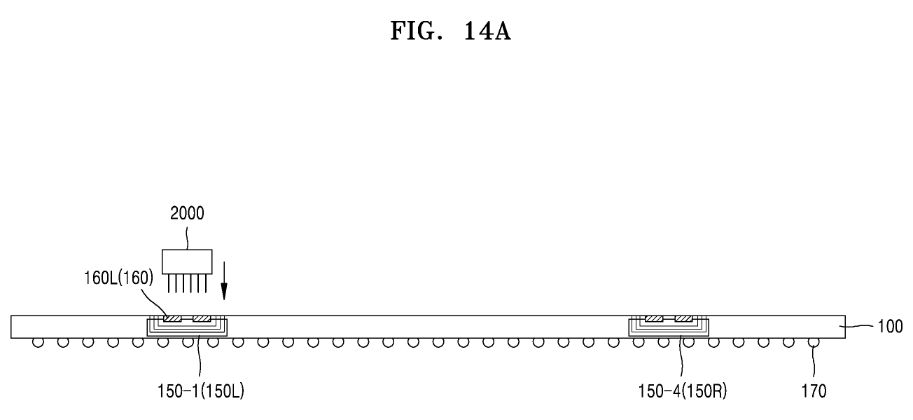

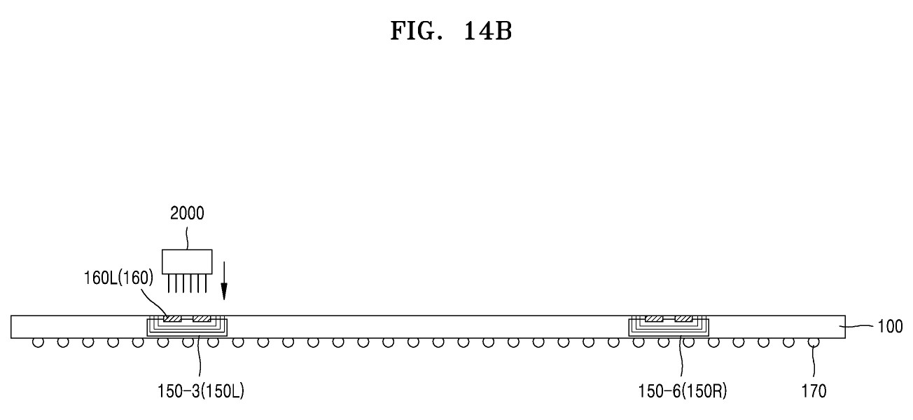

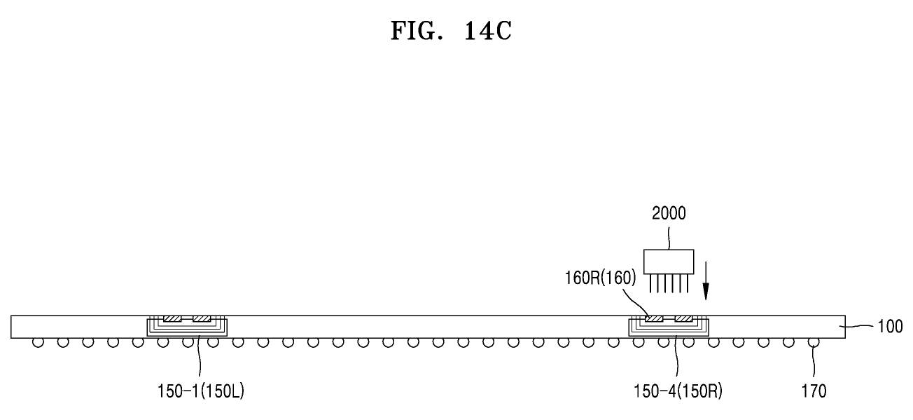

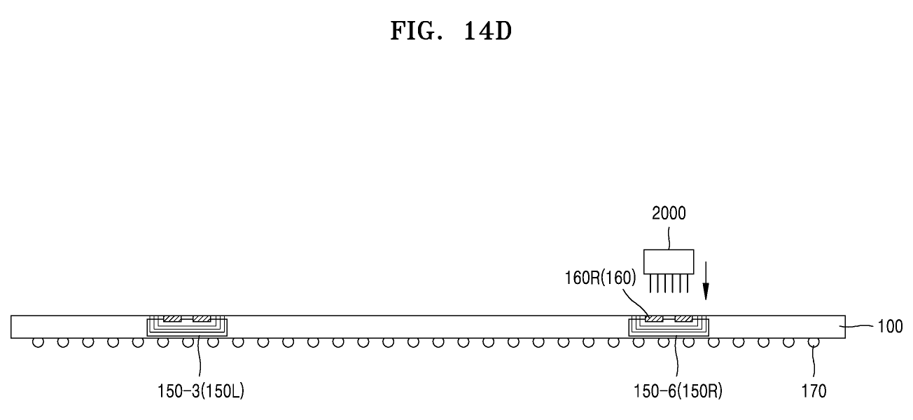

In contrast, in the testing method for the interposer 100 of an embodiment of FIG. 13B, the test may be performed through the test pads 160 on the Si-bridge 150. As described above, the test pad 160 may be formed to have a wide pitch, and accordingly, the test may be easily performed through test equipment 2000 without an intermediate medium, such as the pin adapter PA. In FIG. 13B, the test equipment 2000 simply shows only the test socket or the prober. In addition, the testing method for the interposer 100 of an embodiment may be performed as an interim test. That is, before the first semiconductor device 300 and the second semiconductor device 400 are mounted on the interposer 100, the interim test on the Si-bridge 150 of the interposer 100 may be performed. Accordingly, an increase in loss may be prevented by diagnosing a defect at an early stage. Furthermore, as described in the testing method for the interposer 100 in FIGS. 14A to 14B below, the Si-bridges 150 are arranged in the interposer 100 with a repeating and symmetrical structure. Thus, the test may be performed quickly by repeatedly performing the test while moving the position through the test equipment 2000.

In addition, in the case of the testing method for the interposer InP of the comparative example, since the test is performed after the first semiconductor device CH1 and the second semiconductor device CH2 are mounted thereon, the test may be performed on the lower surface of the interposer InP through the first connection terminal S1. In contrast, in the testing method for the interposer 100 of an embodiment, since the test is performed before the first semiconductor device 300 and the second semiconductor device 400 are mounted thereon, the test may be performed on the upper surface of the interposer 100 through the test pad 160.

FIGS. 14A to 14D are conceptual diagrams schematically illustrating a testing method for the interposer, according to an embodiment. The descriptions are made with reference to FIGS. 1A to 1C together, and the details described with reference to FIGS. 1A and 13B are briefly described or omitted.

Referring to FIG. 14A, in the testing method for the interposer 100 of an embodiment, first, the interim test on the first Si-bridge 150-1 of the left Si-bridge 150L in the interposer 100 is performed through the test pads 160. As described above, six Si-bridges 150 may be arranged in the interposer 100. Specifically, the left Si-bridge 150L may include first to third Si-bridges 150-1 to 150-3, and the right Si-bridge 150R may include fourth to sixth Si-bridges 150-4 to 150-6. The first to third Si-bridges 150-1 to 150-3 may have the same structure. Accordingly, the test pads 160, for example, the left test pads 160L of the first to third Si-bridges 150-1 to 150-3 may have the same arrangement structure. In addition, the fourth to sixth Si-bridges 150-4 to 150-6 may have the same structure. Accordingly, the test pads 160, for example, the right test pads 160R of the fourth to fourth Si-bridges 150-4 to 150-6 may have the same arrangement structure.

On the other hand, the left Si-bridge 150L and the right Si-bridge 150R may have a structure that is symmetrical to each other. For example, the left test pad 160L of the left Si-bridge 150L may have a structure that is symmetrical to the right test pad 160R of the right Si-bridge 150R. The symmetry may correspond to, for example, point symmetry.

Moreover, the interim test may refer to a test before the first semiconductor device 300 and the second semiconductor device 400 are mounted on the interposer 100 as described above. In addition, the interim test may be performed through the test equipment 2000 without an intermediate medium, such as a pin adapter. In FIGS. 14A to 14D, the test equipment 2000 simply shows only the test socket or the prober.

Referring to FIG. 14B, after the interim test on the first Si-bridge 150-1, the interim test on the second Si-bridge 150-2 is performed through the test pad 160. Next, the interim test on the third Si-bridge 150-3 is performed through the test pad 160. Once the interim test on the third Si-bridge 150-3 is completed, the interim test on the left Si-bridge 150L may be completed.

Referring to FIG. 14C, after completing the interim test on the left Si-bridge 150L, the interim test on the fourth Si-bridge 150-4 of the right Si-bridge 150R is performed through the test pads 160. On the other hand, since the right test pad 160R has a point symmetrical structure with the left test pad 160L, the interposer 100 may be rotated by 180°, or the test socket or the prober of the test equipment 2000 may be rotated at 180° when the interim test on the fourth Si-bridge 150-4 is performed.

Referring to FIG. 14D, after the interim test on the fourth Si-bridge 150-4, the interim test on the fifth Si-bridge 150-5 is performed through the test pads 160. Subsequently, the sixth Si-bridge 150-6 is performed through the test pads 160. Once the interim test on the sixth Si-bridge 150-6 is completed, the interim test on the right Si-bridge 150R may be completed, thereby completing the test on the corresponding interposer 100.

While the inventive concept has been particularly shown and described with reference to embodiments thereof, it will be understood that various changes in form and details may be made therein without departing from the spirit and scope of the following claims.

What is claimed is:

1. An interposer comprising:
a body layer;
a wiring layer disposed on the body layer;
a through post penetrating through the body layer;
an interposer pad disposed on the wiring layer; and
a test pad disposed on a connection area of the wiring layer and connected to a portion of the interposer pad.

2. The interposer of claim 1, further comprising a silicon (Si)-bridge arranged in the body layer and the wiring layer, wherein the Si-bridge constitutes the connection area, and the test pad is disposed on the Si-bridge.

3. The interposer of claim 2, wherein, when a first semiconductor device and a second semiconductor device are arranged adjacent to each other on an upper surface of the interposer, the first semiconductor device and the second semiconductor device are connected to the interposer pad on the Si-bridge, and
the test pad is not connected to the first semiconductor device or the second semiconductor device and is used when an interim test on a state of a wire of the Si-bridge is performed before the first semiconductor device and the second semiconductor device are mounted on the interposer.

4. The interposer of claim 2, wherein, when a first semiconductor device is arranged at a center of an upper surface of the interposer in a first direction, and second semiconductor devices are disposed on the upper surface of the interposer on both sides of the first semiconductor device in the first direction, the Si-bridge comprises a first Si-bridge overlapping a portion of each of the first semiconductor device and at least one of the second semiconductor devices on one side of the first semiconductor device in the first direction, and a second Si-bridge overlapping a portion of each of the first semiconductor device and at least another one of the second semiconductor devices on the other side of the first semiconductor device in the first direction,
the test pad comprises a first test pad on the first Si-bridge and a second test pad on the second Si-bridge, and
the first test pad and the second test pad are arranged in a symmetrical structure to each other.

5. The interposer of claim 4, wherein, when a plurality semiconductor devices of the second semiconductor devices are respectively disposed on both sides of the first semiconductor device, a plurality of first Si-bridges and a plurality of second Si-bridges are respectively disposed on both sides of the first semiconductor device,
wherein the plurality of first Si-bridges are implemented as one semiconductor chip, and the plurality of second Si-bridges are implemented as one semiconductor chip, or
each of the plurality of first Si-bridges is implemented as a semiconductor chip, and each of the plurality of second Si-bridges is implemented as a semiconductor chip.

6. The interposer of claim 4, wherein the first Si-bridge and the second Si-bridge each include a plurality of net lines, the first test pad is connected to first net lines that are part of the plurality of net lines, the second test pad is connected to second net lines that are part of the plurality of net lines, and the first net lines and the second net lines have a symmetrical structure to each other.

7. The interposer of claim 6, wherein the first net lines and the second net lines are selected from among the plurality of net lines by a length of the net lines, a number of interposer pads connected to the net lines, or other set criteria.

8. The interposer of claim 1, wherein, when a first semiconductor device and a second semiconductor device are arranged adjacent to each other on an upper surface of the interposer, the first semiconductor device and the second semiconductor device are connected to the interposer pad on the connection area, and
the test pad is not connected to the first semiconductor device or the second semiconductor device and is used when an interim test is performed on a state of wires in the connection area before the first semiconductor device and the second semiconductor device are mounted on the interposer.

9. The interposer of claim 1, wherein a pitch of the test pad is greater than a pitch of the interposer pad.

10. A semiconductor package comprising:
a package substrate;
an interposer on the package substrate;
at least one first semiconductor device arranged in a central portion on an upper surface of the interposer in a first direction; and
second semiconductor devices disposed on the upper surface of the interposer on both sides of the at least one first semiconductor device in the first direction,
wherein the interposer comprises a body layer, a wiring layer disposed on the body layer, a through post penetrating through the body layer, an interposer pad disposed on the wiring layer, and a test pad disposed on a connection area of the wiring layer and connected to a portion of the interposer pad.

11. The semiconductor package of claim 10, wherein the at least one first semiconductor device comprises a logic device, the second semiconductor devices comprise a high bandwidth memory (HBM) package, the interposer further comprises a silicon (Si)-bridge arranged in the body layer and the wiring layer, the Si-bridge constitutes the connection area, and the test pad is disposed on the Si-bridge.

12. The semiconductor package of claim 11, wherein the Si-bridge comprises a first Si-bridge overlapping a portion of each of the at least one first semiconductor device and at least one of the second semiconductor devices in one side of the at least one first semiconductor device in the first direction, and a second Si-bridge overlapping a portion of each of the at least one first semiconductor device and at least another one of the second semiconductor devices on the other side of the at least one first semiconductor device in the first direction,
the test pad comprises a first test pad on the first Si-bridge and a second test pad on the second Si-bridge, and
the first test pad and the second test pad are arranged in a symmetrical structure to each other.

13. The semiconductor package of claim 12, wherein, when a plurality semiconductor devices of the second semiconductor devices are respectively arranged on both sides of the at least one first semiconductor device, a plurality of first Si-bridges and a plurality of second Si-bridges are respectively disposed on both sides of the at least one first semiconductor device,
wherein the plurality of first Si-bridges are implemented as one semiconductor chip, and the plurality of second Si-bridges are implemented as one semiconductor chip, or
each of the plurality of first Si-bridges is implemented as a semiconductor chip, and each of the plurality of second Si-bridges is implemented as a semiconductor chip.

14. The semiconductor package of claim 12, wherein the first Si-bridge and the second Si-bridge each comprise a plurality of net lines, the first test pad is connected to first net lines that are part of the plurality of net lines, the second test pad is connected to second net lines that are part of the plurality of net lines, and the first net lines and the second net lines have a symmetrical structure to each other.

15. The semiconductor package of claim 10, wherein the at least one first semiconductor device and the second semiconductor devices are connected to the interposer pad on the connection area, and
the test pad is not connected to the at least one first semiconductor device and the second semiconductor devices and is used for an interim test of a state of wires in the connection area before the first semiconductor device and the second semiconductor device are mounted on the interposer.

16. A semiconductor package comprising:
a package substrate;
an interposer on the package substrate;
at least one logic device arranged in a central portion of an upper surface of the interposer in a first direction; and
a high bandwidth memory (HBM) package disposed on the upper surface of the interposer on both sides of the at least one logic device in the first direction,
wherein the interposer comprises a body layer, a wiring layer disposed on the body layer, a silicon (Si)-bridge arranged in the body layer and the wiring layer, a through post penetrating through the body layer, an interposer pad disposed on the wiring layer and the Si-bridge, and a test pad disposed on the Si-bridge and connected to a portion of the interposer pad.

17. The semiconductor package of claim 16, wherein the Si-bridge comprises a first Si-bridge overlapping a portion of each of the at least one logic device and the HBM package in one side of the at least one logic device in the first direction, and a second Si-bridge overlapping a portion of each of the at least one logic device and the HBM package on the other side of the at least one logic device in the first direction, wherein the test pad comprises a first test pad on the first Si-bridge and a second test pad on the second Si-bridge, and the first test pad and the second test pad are arranged in a symmetrical structure to each other.

18. The semiconductor package of claim 17, wherein the first Si-bridge and the second Si-bridge each comprise a plurality of net lines, the first test pad is connected to first net lines that are part of the net lines, the second test pad is connected to second net lines that are part of the net lines, and the first net lines and the second net lines have a symmetrical structure to each other.

19. The semiconductor package of claim 16, wherein the at least one logic device comprises a first logic device and a second logic device arranged adjacent to each other in a second direction perpendicular to the first direction, and
a first chiplet is arranged adjacent to the first logic device at an outer portion in the second direction, and a second chiplet is arranged adjacent to the second logic device at an outer portion in the second direction.

20. The semiconductor package of claim 19, wherein a first portion of the wiring layer connecting the first logic device to the first chiplet and a second portion of the wiring layer connecting the second logic device to the second chiplet have substantially the same design as each other.
